(19) United States
(12) Patent Application Publication
(10) Pub. No.: US 2026/0058676 A1
(43) Pub. Date: Feb. 26, 2026

(54) SHAPING CODE USING SERIAL PROCESSING

(71) Applicant: QUALCOMM INCORPORATED, San Diego, CA (US)

(72) Inventors: Liangming Wu, Beijing (CN); Wei Liu, Beijing (CN); Kexin Xiao, Shanghai (CN); Changlong Xu, Beijing (CN); Jian Li, Shanghai (CN); Wei Yang, San Diego, CA (US); Jing Jiang, San Diego, CA (US); Hao Xu, Beijing (CN)

(21) Appl. No.: 19/102,359

(22) PCT Filed: Oct. 8, 2022
(86) PCT No.: PCT/CN2022/123760

§ 371 Date: Feb. 7, 2025

(51) Int. Cl. H03M 13/25; H03M 13/11; H04L 1/00

(52) U.S. Cl. CPC H03M 13/253; H03M 13/11; H04L 1/0053

(57) ABSTRACT

Methods, systems, and devices for wireless communication are described. The described techniques provide for a device to generate, using a first decoder of the device, a first set of shaping bits associated with a first subset of information bits. The device may generate, using a second decoder of the first device, a second set of shaping bits based at least in part on a first set of concatenated bits. The first set of concatenated bits may include the first set of shaping bits and a second subset of the information bits. The device may apply mask vectors to the first subset of the information bits to obtain a first set of shaped bits and a second set of shaped bits. The device may transmit, based on applying the mask vectors, a message including the first set of shaped bits and the second set of shaped bits.

### CROSS REFERENCE

This application is a 371 National Stage of PCT Application No. PCT/CN2022/123760, filed on Oct. 8, 2022, entitled “SHAPING CODE USING SERIAL PROCESSING”, and assigned to the assignee hereof. The disclosure of the prior Application is considered part of and is incorporated by reference into this Patent Application.

### FIELD OF TECHNOLOGY

The following relates to wireless communication, including shaping code using serial processing.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

### SUMMARY

The described techniques relate to improved methods, systems, devices, and apparatuses that support shaping code using serial processing. For example, the described techniques provide for a device to generate, using a first decoder of the device, a first set of shaping bits associated with a first subset of a set of information bits. The device may generate, using a second decoder of the first device, a second set of shaping bits based at least in part on a first set of concatenated bits. The first set of concatenated bits may include at least the first set of shaping bits and a second subset of the set of information bits. The device may apply a first mask vector to the first subset of the set of information bits based on a first encoder to obtain a first set of shaped bits, and the device may apply a second mask vector to the first set of concatenated bits based at least in part on the first encoder of the first device to obtain a second set of shaped bits. The device may transmit, based on applying the mask vectors, a message including the first set of shaped bits and the second set of shaped bits.

An apparatus for wireless communications at a first device is described. The apparatus may include a processor, memory coupled with the processor, and instructions stored in the memory. The instructions may be executable by the processor to cause the apparatus to generate, using a first decoder of the first device, a first set of shaping bits associated with a first subset of a set of information bits, generate, using a second decoder of the first device, a second set of shaping bits based on a first set of concatenated bits including at least the first set of shaping bits and a second subset of the set of information bits, apply a second mask vector to the first set of concatenated bits based on a first encoder of the first device to obtain a second set of shaped bits, and transmit, based on applying the second mask vector, a message including at least the second set of shaped bits.

A method for wireless communications at a first device is described. The method may include generating, using a first decoder of the first device, a first set of shaping bits associated with a first subset of a set of information bits, generating, using a second decoder of the first device, a second set of shaping bits based on a first set of concatenated bits including at least the first set of shaping bits and a second subset of the set of information bits, applying a second mask vector to the first set of concatenated bits based on a first encoder of the first device to obtain a second set of shaped bits, and transmitting, based on applying the second mask vector, a message including at least the second set of shaped bits.

Another apparatus for wireless communications at a first device is described. The apparatus may include means for generating, using a first decoder of the first device, a first set of shaping bits associated with a first subset of a set of information bits, means for generating, using a second decoder of the first device, a second set of shaping bits based on a first set of concatenated bits including at least the first set of shaping bits and a second subset of the set of information bits, means for applying a second mask vector to the first set of concatenated bits based on a first encoder of the first device to obtain a second set of shaped bits, and means for transmitting, based on applying the second mask vector, a message including at least the second set of shaped bits.

A non-transitory computer-readable medium storing code for wireless communications at a first device is described. The code may include instructions executable by a processor to generate, using a first decoder of the first device, a first set of shaping bits associated with a first subset of a set of information bits, generate, using a second decoder of the first device, a second set of shaping bits based on a first set of concatenated bits including at least the first set of shaping bits and a second subset of the set of information bits, apply a second mask vector to the first set of concatenated bits based on a first encoder of the first device to obtain a second set of shaped bits, and transmit, based on applying the second mask vector, a message including at least the second set of shaped bits.

Some examples of the method, apparatuses, and non-transitory computer-readable medium described herein may further include operations, features, means, or instructions for applying a first mask vector to the first subset of the set of information bits based on the first encoder of the first device to obtain a first set of shaped bits, where the message further includes the first set of shaped bits.

Some examples of the method, apparatuses, and non-transitory computer-readable medium described herein may further include operations, features, means, or instructions for generating, using a third encoder of the first device, a set of parity bits based on the first set of shaped bits, the second set of shaped bits, and the second set of shaping bits, where the message further includes the set of parity bits.

Some examples of the method, apparatuses, and non-transitory computer-readable medium described herein may further include operations, features, means, or instructions for generating, using a third decoder of the first device, a third set of shaping bits based on a second set of concatenated bits, the second set of concatenated bits including at least the second set of shaping bits and a third subset of the set of information bits.

Some examples of the method, apparatuses, and non-transitory computer-readable medium described herein may further include operations, features, means, or instructions for applying a third mask vector to the second set of concatenated bits based on a second encoder of the first device to obtain a third set of shaped bits and generating a third set of concatenated bits including at least the second set of shaped bits and the third set of shaping bits, where the message further includes the third set of concatenated bits.

Some examples of the method, apparatuses, and non-transitory computer-readable medium described herein may further include operations, features, means, or instructions for generating, using a third encoder of the first device, a set of parity bits based on the third set of concatenated bits, the second set of shaped bits, and the first subset of the set of information bits, where the message further includes the set of parity bits.

In some examples of the method, apparatuses, and non-transitory computer-readable medium described herein, a quantity of bits of the first subset of the set of information bits may be greater than a quantity of bits of the third subset of the set of information bits.

In some examples of the method, apparatuses, and non-transitory computer-readable medium described herein, transmitting the message may include operations, features, means, or instructions for mapping the second set of shaped bits to one or more symbols to obtain a set of mapped bits and transmitting, based on applying the second mask vector and on the mapping, a message including at least the set of mapped bits.

In some examples of the method, apparatuses, and non-transitory computer-readable medium described herein, generating the first set of shaping bits may include operations, features, means, or instructions for generating, using the first decoder of the first device, the first set of shaping bits associated with the first subset of the set of information bits based on one or more log-likelihood ratio values.

Some examples of the method, apparatuses, and non-transitory computer-readable medium described herein may further include operations, features, means, or instructions for determining that transmitting the message including at least the second set of shaped bits consumes less power than a transmission including the second subset of the set of information bits, where applying the second mask vector may be based on the message consuming less power than the transmission.

In some examples of the method, apparatuses, and non-transitory computer-readable medium described herein, a quantity of bits of the first subset of the set of information bits may be greater than a quantity of bits of the second subset of the set of information bits.

An apparatus for wireless communications at a second device is described. The apparatus may include a processor, memory coupled with the processor, and instructions stored in the memory. The instructions may be executable by the processor to cause the apparatus to receive a message including a set of multiple shaped bits and a first set of shaping bits, the set of multiple shaped bits including at least a first set of shaped bits and a second set of shaped bits, decode, based on the first set of shaping bits, the first set of shaped bits to obtain a first set of information bits and a second set of shaping bits, and decode, based on the second set of shaping bits, the second set of shaped bits to obtain a second set of information bits.

A method for wireless communications at a second device is described. The method may include receiving a message including a set of multiple shaped bits and a first set of shaping bits, the set of multiple shaped bits including at least a first set of shaped bits and a second set of shaped bits, decoding, based on the first set of shaping bits, the first set of shaped bits to obtain a first set of information bits and a second set of shaping bits, and decoding, based on the second set of shaping bits, the second set of shaped bits to obtain a second set of information bits.

Another apparatus for wireless communications at a second device is described. The apparatus may include means for receiving a message including a set of multiple shaped bits and a first set of shaping bits, the set of multiple shaped bits including at least a first set of shaped bits and a second set of shaped bits, means for decoding, based on the first set of shaping bits, the first set of shaped bits to obtain a first set of information bits and a second set of shaping bits, and means for decoding, based on the second set of shaping bits, the second set of shaped bits to obtain a second set of information bits.

A non-transitory computer-readable medium storing code for wireless communications at a second device is described. The code may include instructions executable by a processor to receive a message including a set of multiple shaped bits and a first set of shaping bits, the set of multiple shaped bits including at least a first set of shaped bits and a second set of shaped bits, decode, based on the first set of shaping bits, the first set of shaped bits to obtain a first set of information bits and a second set of shaping bits, and decode, based on the second set of shaping bits, the second set of shaped bits to obtain a second set of information bits.

In some examples of the method, apparatuses, and non-transitory computer-readable medium described herein, decoding the second set of shaped bits may include operations, features, means, or instructions for decoding, based on the second set of shaping bits, the second set of shaped bits to obtain the second set of information bits and a third set of shaping bits.

Some examples of the method, apparatuses, and non-transitory computer-readable medium described herein may further include operations, features, means, or instructions for decoding, based on the third set of shaping bits, the third set of shaped bits to obtain a third set of information bits.

In some examples of the method, apparatuses, and non-transitory computer-readable medium described herein, a quantity of bits of the third set of information bits may be greater than a quantity of bits of the second set of information bits.

In some examples of the method, apparatuses, and non-transitory computer-readable medium described herein, decoding the first set of shaped bits may include operations, features, means, or instructions for applying a mask vector to the first set of shaped bits to obtain the first set of information bits and the second set of shaping bits, where the mask vector may be based on the first set of shaping bits.

In some examples of the method, apparatuses, and non-transitory computer-readable medium described herein, a quantity of bits of the second set of information bits may be greater than a quantity of bits of the first set of information bits.

Some examples of the method, apparatuses, and non-transitory computer-readable medium described herein may further include operations, features, means, or instructions for mapping the set of multiple shaped bits and the first set of shaping bits to one or more symbols, where decoding the first set of shaped bits may be based on the mapping.

In some examples of the method, apparatuses, and non-transitory computer-readable medium described herein, the message further includes a set of parity bits.

### BRIEF DESCRIPTION OF THE DRAWINGS

FIG. 1 illustrates an example of a wireless communications system that supports shaping code using serial processing in accordance with one or more aspects of the present disclosure.

FIG. 2 illustrates an example of a wireless communications system that supports shaping code using serial processing in accordance with one or more aspects of the present disclosure.

FIG. 3 illustrates an example of an encoding scheme that supports shaping code using serial processing in accordance with one or more aspects of the present disclosure.

FIG. 4 illustrates an example of a mapping scheme that supports shaping code using serial processing in accordance with one or more aspects of the present disclosure.

FIG. 5 illustrates an example of a process flow that supports shaping code using serial processing in accordance with one or more aspects of the present disclosure.

FIGS. 6 and 7 show block diagrams of devices that support shaping code using serial processing in accordance with one or more aspects of the present disclosure.

FIG. 8 shows a block diagram of a communications manager that supports shaping code using serial processing in accordance with one or more aspects of the present disclosure.

FIG. 10 shows a diagram of a system including a UE that supports shaping code using serial processing in accordance with one or more aspects of the present disclosure.

FIG. 9 shows a diagram of a system including a network entity that supports shaping code using serial processing in accordance with one or more aspects of the present disclosure.

FIGS. 11 through 15 show flowcharts illustrating methods that support shaping code using serial processing in accordance with one or more aspects of the present disclosure.

### DETAILED DESCRIPTION

Devices operating within a wireless communications system may perform bit-level encoding of information bits prior to performing a transmission. In some cases, a transmit power associated with the transmission may be affected by a bit sequence of information to be transmitted. Accordingly, some devices may employ shaping techniques to modify information bits associated with the information to be transmitted and reduce the transmit power. For example, a device may generate a set of shaping bits (e.g., using a shaping encoder) to use for masking the information bits. The device may encode the masked information bits and the shaping bits for the transmission. A receiving device may receive the transmission and may re-encode the information bits according to the shaping bits to obtain the information bits (e.g., unmasked information bits). In some cases, however, the quantity of shaping bits may exceed an allocation for mapping the shaping bits for the transmission. A transmitting device may encode some of the shaping bits in a bit vector intended for information bits, however, this may result in unknown bits due to one or more of the information bits being omitted. Such an omission of information bits may cause a degradation in performance, for example, when the transmitting device generates a log-likelihood ratio (LLR) associated with the information bits.

In accordance with examples described herein, a device may perform bit shaping using serial processing of bits associated with a set of information bits for a transmission. For example, the device may generate a first set of shaping bits associated with a first subset of the information bits, and the device may encode (e.g., mask) the first subset of information bits based on the first set of shaping bits. The device may then generate a first set of concatenated bits based on a second subset of the information bits and the first set of shaping bits, and the device may generate a second set of shaping bits based on the first set of concatenated bits. The device may encode (e.g., mask) the first set of concatenated bits based on the second set of shaping bits. The device may continue this process for each subset of the information bits. That is, for n subsets of the information bits, the device may perform this process for each i^{th} subset, where 1<i<n.

The device may (e.g., subsequently) generate a last set of concatenated bits based on a last subset (e.g., an n^{th} subset) of the information bits and a second-to-last (e.g., n−1) set of shaping bits. In some examples, the last set of concatenated bits may be smaller in length, as the last subset of the information bits may contain less bits than other subsets of the information bits. The device may encode the last set of concatenated bits based on a last set (e.g., an n^{th} set) of shaping bits, and the device may concatenate the last set of shaping bits to the last set of concatenated bits. Accordingly, the device may perform shaping (e.g., encoding or masking) of the information bits and include information associated with the shaping bits without omitting information bits by performing encoding in a serial manner, which may help reduce or prevent performance degradation associated with unknown information bits and unknown LLRs.

Aspects of the disclosure are initially described in the context of wireless communications systems. Aspects of the disclosure are additionally described in the context of encoding schemes and mapping schemes. Aspects of the disclosure are further illustrated by and described with reference to process flows, apparatus diagrams, system diagrams, and flowcharts that relate to shaping code using serial processing.

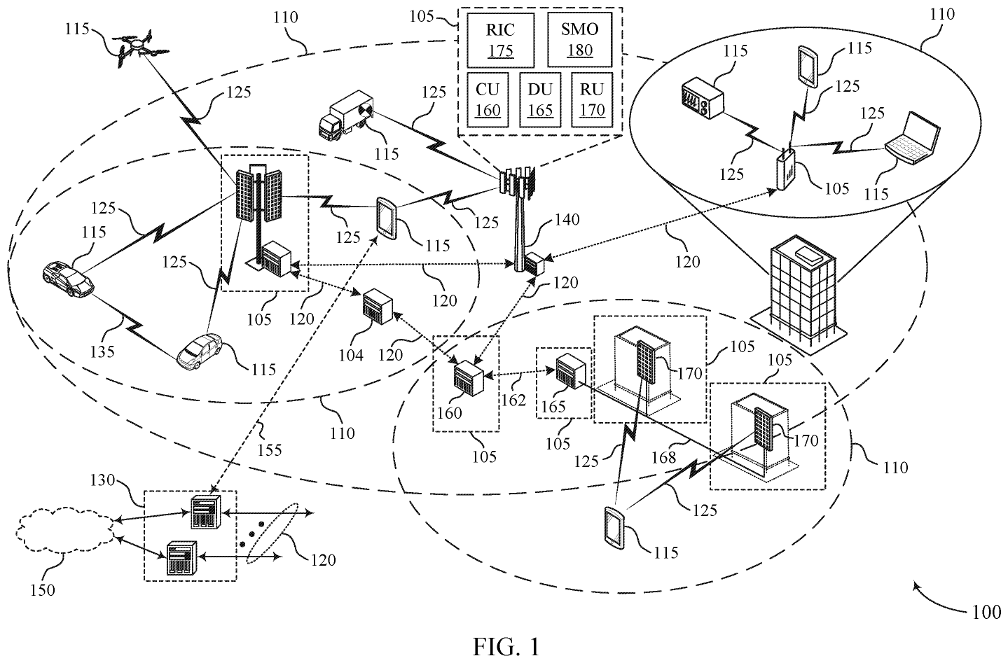

FIG. 1 illustrates an example of a wireless communications system 100 that supports shaping code using serial processing in accordance with one or more aspects of the present disclosure. The wireless communications system 100 may include one or more network entities 105, one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via one or more communication links 125 (e.g., a radio frequency (RF) access link). For example, a network entity 105 may support a coverage area 110 (e.g., a geographic coverage area) over which the UEs 115 and the network entity 105 may establish one or more communication links 125.

The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with the core network 130, or with one another, or both. For example, network entities 105 may communicate with the core network 130 via one or more backhaul communication links 120 (e.g., in accordance with an S1, N2, N3, or other interface protocol). In some examples, network entities 105 may communicate with one another via a backhaul communication link 120 (e.g., in accordance with an X2, Xn, or other interface protocol) either directly (e.g., directly between network entities 105) or indirectly (e.g., via a core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication links 120, midhaul communication links 162, or fronthaul communication links 168 may be or include one or more wired links (e.g., an electrical link, an optical fiber link), one or more wireless links (e.g., a radio link, a wireless optical link), among other examples or various combinations thereof. A UE 115 may communicate with the core network 130 via a communication link 155.

One or more of the network entities 105 described herein may include or may be referred to as a base station 140 (e.g., a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within a single network entity 105 (e.g., a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU) 160, a distributed unit (DU) 165, a radio unit (RU) 170, a RAN Intelligent Controller (RIC) 175 (e.g., a Near-Real Time RIC (Near-RT RIC), a Non-Real Time RIC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaption protocol (SDAP), Packet Data Convergence Protocol (PDCP)). The CU 160 may be connected to one or more DUs 165 or RUs 170, and the one or more DUs 165 or RUS 170 may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or more RUs 170). In some cases, a functional split between a CU 160 and a DU 165, or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (e.g., F1, F1-c, F1-u), and a DU 165 may be connected to one or more RUs 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities 105 that are in communication via such communication links.

In wireless communications systems (e.g., wireless communications system 100), infrastructure and spectral resources for radio access may support wireless backhaul link capabilities to supplement wired backhaul connections, providing an IAB network architecture (e.g., to a core network 130). In some cases, in an IAB network, one or more network entities 105 (e.g., IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (e.g., a donor base station 140). The one or more donor network entities 105 (e.g., IAB donors) may be in communication with one or more additional network entities 105 (e.g., IAB nodes 104) via supported access and backhaul links (e.g., backhaul communication links 120). IAB nodes 104 may include an IAB mobile termination (IAB-MT) controlled (e.g., scheduled) by DUs 165 of a coupled IAB donor. An IAB-MT may include an independent set of antennas for relay of communications with UEs 115, or may share the same antennas (e.g., of an RU 170) of an IAB node 104 used for access via the DU 165 of the IAB node 104 (e.g., referred to as virtual IAB-MT (VIAB-MT)). In some examples, the IAB nodes 104 may include DUs 165 that support communication links with additional entities (e.g., IAB nodes 104, UEs 115) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

In the case of the techniques described herein applied in the context of a disaggregated RAN architecture, one or more components of the disaggregated RAN architecture may be configured to support shaping code using serial processing as described herein. For example, some operations described as being performed by a UE 115 or a network entity 105 (e.g., a base station 140) may additionally, or alternatively, be performed by one or more components of the disaggregated RAN architecture (e.g., IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (e.g., an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

In some examples, a network entity 105 (e.g., a base station 140, an RU 170) may be movable and therefore provide communication coverage for a moving coverage area 110. In some examples, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs 115 via a device-to-device (D2D) communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to each of the other UEs 115 in the group. In some examples, a network entity 105 may facilitate the scheduling of resources for D2D communications. In some other examples, D2D communications may be carried out between the UEs 115 without an involvement of a network entity 105.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than 100 kilometers) compared to communications using the smaller frequencies and longer waves of the high frequency (HF) or very high frequency (VHF) portion of the spectrum below 300 MHZ.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

In some examples, a bit-level and a symbol transmit power may be related. For example, bit 0, or a most-significant bit, may have more impact on a transmit power of the symbol than other bits. If, for example, the most-significant bit is set to ‘0’, a transmit power used to transmit the symbol may be lower than if the most-significant bit were set to ‘1’.

Some systems may modify the transmit bit sequence, which may lead to a lower transmit power. For example, a transmitting device (e.g., a UE 115, a network entity 105, or another device) may use a bitmask on the most-significant bit to reduce the transmit power. The transmitting device may use a shaping encoder to mask the information bits and jointly encode the shaped information bits and information for shaping. The decoder side may jointly decode the shaped information bits and the information for shaping, then reencode the bits to obtain the original information bits.

In some examples, the transmitting device may input information bits to an LLR generator to obtain LLR values for the information bits. The transmitting device may use a channel decoder to obtain shaping bits from the LLR values. The transmitting device may generate a bitmask from the shaping bits and apply the bitmask to the information bits to obtain shaped information bits. The transmitting device may jointly encode the shaping bits and the shaped information bits and map the bits to a symbol to obtain a shaped symbol. The transmitting device may transmit the shaped symbol over a wireless channel to a receiving device (e.g., a UE 115, network entity 105, or another device). The receiving device may decode the bits from the shaped symbol to recover the shaped information and the shaping bits. The receiving device may generate a demasking vector from the shaping bits and apply the demasking vector to the shaped information bits to recover the original information bits.

When generating the LLR values, the transmitting device may generate a cover code that increases or maximizes a power saving after bit-masking. The LLR values may be generated according to how much power is saved by flipping each bit. For example, if the original transmit bits (u₀, u₁) are set to (1,1), transmitting bit u₀ without flipping may have an associated transmit power of 25. Flipping the u₀ bit may result in a transmit power of 9. Therefore, flipping the u₀ bit may have an associated transmit power change of ‘16’, or flipping the u₀ bit may have a transmit power reduction of ‘16’, so the LLR for the first bit may be 16.

In some cases, however, the quantity of shaping bits used for bit-masking may exceed an allocation (e.g., a bit allocation) for mapping the shaping bits for a transmission by the transmitting device. In some examples, the transmitting device may encode some of the shaping bits in a bit vector intended for information bits, however, this may result in unknown bits due to one or more of the information bits being omitted. This may cause a degradation in performance, for example, when the transmitting device generates LLR values associated with the information bits as this may result in unknown LLR values.

In accordance with examples as described herein, a device (e.g., a UE 115, a network entity 105) may perform bit shaping using serial processing techniques for shaping bits associated with a set of information bits for a transmission. For example, the device may segment the information bits into multiple subsets (e.g., blocks or packets), such as an n quantity of subsets. The device may then generate multiple (e.g., n) blocks of shaped bits for the transmission, which may each contain a same or a different quantity of information bits. For example, the device may include a first set of shaping bits corresponding to shaping of a first subset of the information bits (e.g., as known bits or information bits) in a second block that corresponds to a second subset of the information bits. Accordingly, an LLR calculation to obtain LLR values for the second block may be based on the second subset of the information bits and on the first set of shaping bits corresponding to the first subset of the information bits. The device may perform a similar process for each subset of the information bits until the last (e.g., n) subset of information bits. In this case, the shaping bits associated with shaping of the last subset of the information bits may be included in the last block of shaped bits. The device may jointly encode each of the blocks containing the subsets of information bits and the respective shaping bits using an encoder (e.g., a forward error correction (FEC) encoder), and perform transmission of the jointly encoded blocks (e.g., in a message or transport block).

For example, the device may generate a first set of shaping bits associated with a first subset of the information bits, and the device may encode (e.g., mask) the first subset of information bits based on the first set of shaping bits. The device may generate a first set of concatenated bits based on a second subset of the information bits and the first set of shaping bits, and the device may generate a second set of shaping bits based on the first set of concatenated bits. The device may encode (e.g., mask) the first set of concatenated bits based on the second set of shaping bits. The device may continue this process for each subset of the information bits. That is, for n subsets of the information bits, the device may perform this process for each i^{th} subset, where 1<i<n.

The device may (e.g., subsequently) generate a last set of concatenated bits based on a last subset (e.g., an n^{th} subset) of the information bits and a second-to-last (e.g., n−1) set of shaping bits. In some examples, the last set of concatenated bits may be smaller in length, as the last subset of the information bits may contain less bits than other subsets of the information bits. The device may encode the last set of concatenated bits based on a last set (e.g., an n^{th} set) of shaping bits, and the device may concatenate the last set of shaping bits to the last set of concatenated bits. Accordingly, the device may perform shaping (e.g., encoding or masking) of the information bits and include information associated with the shaping bits without omitting information bits by performing encoding in a serial manner, which may avoid performance degradation associated with unknown information bits and resulting unknown LLR.

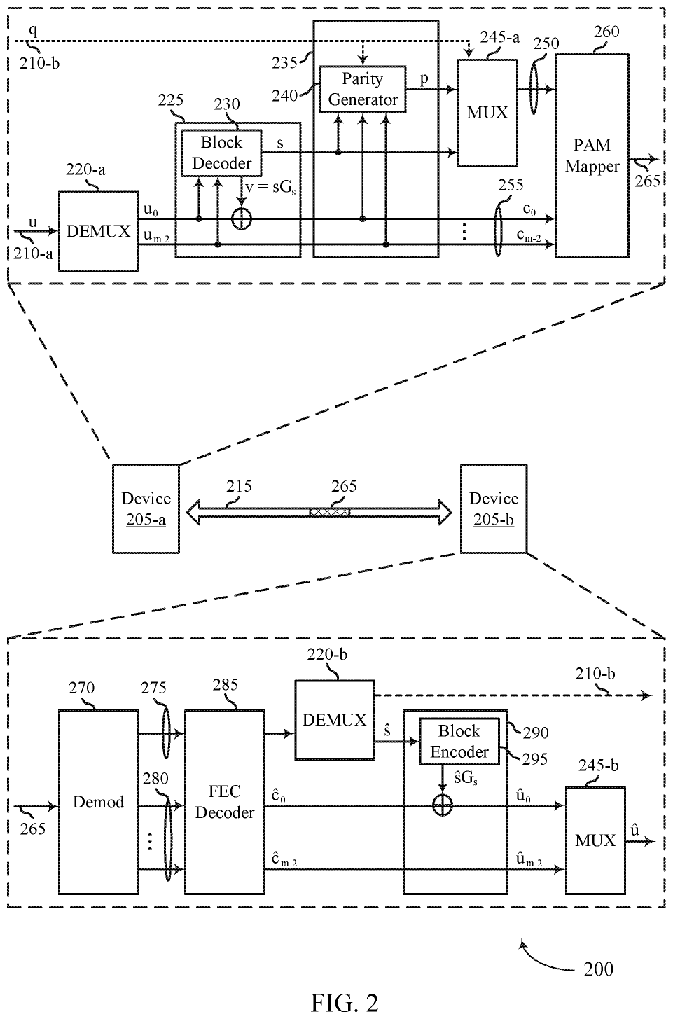

FIG. 2 illustrates an example of a wireless communications system 200 that supports shaping code using serial processing in accordance with one or more aspects of the present disclosure. The wireless communications system 200 may include a device 205-a and a device 205-b, which may be examples of a UE 115, a network entity 105, or another device, as described herein with reference to FIG. 1.

The wireless communications system 200 may support techniques to perform serial shaping of information bits of a transmission. For example, the wireless communications system 200 may support techniques for the device 205-a to shape information bits to be transmitted in a message 265 to device 205-b via communication link 215, which may be an example of a communication link 125 as described herein, with reference to FIG. 1.

The device 205-a may use a demultiplexer (e.g., DEMUX) 220-a to demultiplex information bits 210-a (e.g., stream u) into multiple streams (e.g., u₀, uₘ₋₂, and, in some cases, other streams not shown, where m may correspond to a quantity of bits carried per dimension in a stream, such as an I or Q dimension for a quadrature amplitude modulation (QAM) scheme). For example, the device 205-a may demultiplex stream u to obtain at least a stream u₀ corresponding to the most significant bit of stream u.

The device 205-a may use a shaping encoder 225 to mask (e.g., encode or shape) bits corresponding to the multiple streams to obtain shaped (e.g., masked) bits. For example, the device 205-a may use a block decoder 230 to mask stream ug using a masking vector v. In some examples, the masking vector v may be equal to s*Gₛ, where s may be a set of shaping bits, and Gₛ may be a generator matrix for a wireless channel. The device 205-a may perform masking corresponding to each of the multiple streams using the block decoder 230 or other block decoders 230 not shown. The block decoder 230 may output the set of shaping bits s.

In some examples, the device 205-a may encode the multiple bit streams using a systematic FEC encoder 235. The systematic FEC encoder 235 may include a parity generator 240, which may generate a stream p containing (e.g., one or more) parity bits based on the shaping bits s, and the multiple streams containing the shaped bits. In some examples, the generation of the parity bits using the parity generator 240 may be additionally based on additional information bits 210-b (e.g., stream q).

The device 205-a may multiplex the parity bits (e.g., stream p) and the shaping bits (e.g., stream s) using a multiplexer (e.g., MUX) 245-a. In some examples, the resulting bit stream 250 may represent sign bits, which may correspond to sign values of a transmission associated with the message 265. The sign bits may include bits shaping bits (e.g., from stream s) and parity bits (e.g., from stream p). The bit streams 255 (e.g., stream c₀, stream cₘ₋₂, and other streams corresponding to the shaped bits) may represent amplitude bits, which may correspond to an amplitude of the transmission associated with the message 265.

The device 205-a may map the bit stream 250 and the bit streams 255 using a pulse amplitude modulation (PAM) mapper 260. In some examples, the mapping may include bit-to-symbol mapping of the shaped bits and the parity bits corresponding to the bit stream 250 and the bit streams 255. The PAM mapper 260 may output a message 265, which the device 205-a may transmit to the device 205-b (e.g., via communication link 215).

The device 205-b may demodulate the message 265 using a demodulator 270 (e.g., a demod block). The device 205-b may separate the message into a stream 275 corresponding to the sign bits of the message 265, and streams 280 corresponding to the amplitude bits of the message 265. The device may use an FEC decoder 285 to decode the stream 275 and the streams 280. For example, the FEC decoder 285 may obtain parity bits included in the streams 280 and perform an FEC procedure to check for errors in the message 265. The streams 280 (e.g., stream ĉ₀, stream ĉₘ₋₂, and other streams) may correspond to shaped bits of the message 265.

The device 205-b may demultiplex the sign bits of stream 275 using a demultiplexer 220-b. For example, the demultiplexer 220-b may output additional bits 210-b, and shaping bits ŝ associated with the shaped bits. The device 205-b may use a shaping decoder 290 to obtain the original information bits based on the shaping bits. For example, the shaping decoder may include a block encoder 295. The block encoder may use the shaping bits ŝ and the generator matrix Gₛ to re-encode the shaped bits and obtain the original information bits (e.g., stream û₀, stream ûₘ₋₂, and other streams). Then, device 205-b may multiplex the one or more streams containing the original information bits (e.g., stream û₀, stream ûₘ₋₂, and other streams) using a multiplexer 245-b.

In some cases, the quantity of shaping bits s used for bit-masking may exceed a space allocated for mapping the shaping bits as part of the sign bits (e.g., in stream 250) by the multiplexer 245-a of the device 205-a. For example, the device 205-a may have eight symbols allocated for the stream 250, corresponding to the sign bits. The parity bits may occupy four of these eight symbols, however, the shaping bits may exceed the remaining 4 symbols. In these cases, the device 205-a may encode some of the shaping bits s in a stream of the streams 255 corresponding to the shaped information bits (e.g., a stream ug or a stream u₁). Additionally, or alternatively, the device 205-a may include some of the parity bits in a stream of the streams 255 corresponding to the shaped information bits to include the shaping bits in the stream 250. In either case, this may cause one or more of the information bits 210-a being omitted and may result in unknown bits. This may cause a degradation in performance, for example, when the transmitting device generates LLR values associated with the information bits as this may result in unknown LLR values.

In accordance with examples as described herein, the device 205-a may perform bit shaping using serial processing of bits associated with a set of information bits for a transmission. For example, the device 205-a may segment the information bits 210-a into multiple subsets, such as an n quantity of subsets. The device 205-a may include a first set of shaping bits corresponding to shaping of a first subset of the information bits 210-a (e.g., as known bits or information bits) in a second block that corresponds to a second subset of the information bits. Accordingly, LLR values calculated for the second subset of the information bits may be based on the first set of shaping bits that corresponds to the first subset of the information bits.

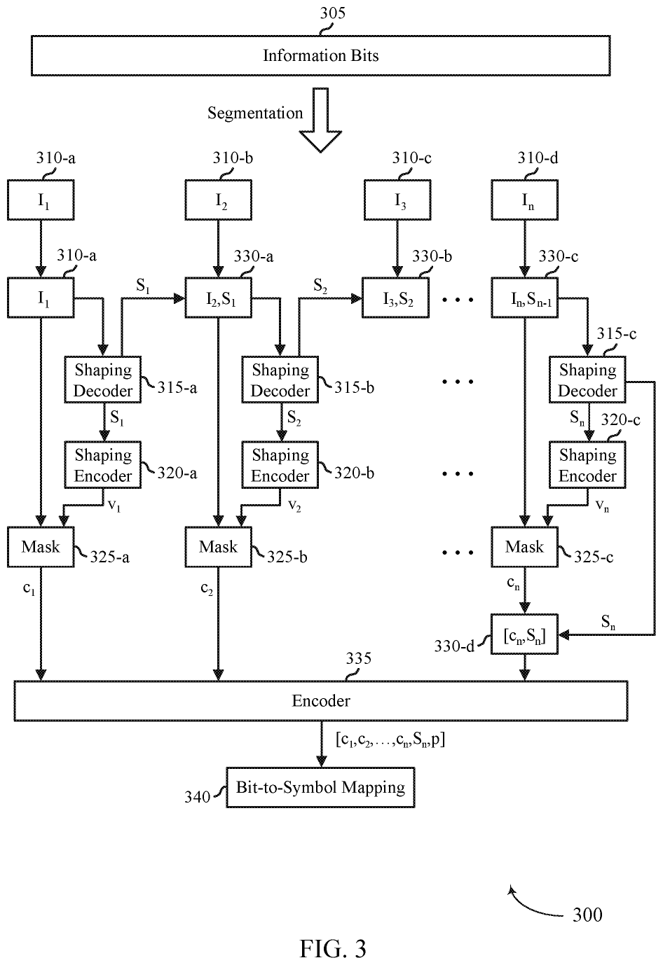

The device 205-a may perform a similar process for each subset of the information bits until the last (e.g., n) subset of information bits. For example, the device 205-a may include shaping bits associated with a second subset of the information bits 210-a in a third block that corresponds to a third subset of the information bits. In the case of the last subset of information bits, the shaping bits associated with shaping of the last subset of the information bits may be included in the last block of shaped bits. The device 205-a may then jointly encode each of the blocks containing the subsets of information bits and the respective shaping bits using the systematic FEC encoder 235, and perform the transmission based on the encoding. The serial processing associated with shaping of the information bits is described in more detail herein, with reference to FIG. 3. Accordingly, the device 205-a may perform bit shaping in a serial manner that may reduce the quantity of unknown information bits, and therefore avoid performance degradation associated with unknown LLR values.

FIG. 3 illustrates an example of an encoding scheme 300 that supports shaping code using serial processing in accordance with one or more aspects of the present disclosure. The encoding scheme 300 may support techniques to perform serial shaping of information bits in a transmission. For example, the encoding scheme 300 may support techniques for a device to shape information bits 305, which may be an example of information bits 210 as described herein, with reference to FIG. 2.

The device may segment the information bits 310 into multiple subsets 310 (e.g., sub-blocks). For example, the device may segment the information bits 310 into an n quantity of subsets 310, such as a first subset 310-a, a second subset 310-b, a third subset 310-c, and a last (e.g., n^{th}) subset 310-d. In some examples, the lengths of the subsets 310 may be different. For example, the first subset 310-a may contain a quantity of information bits 305 greater than the other subsets 310. Additionally, the last subset 310-d may contain a quantity of information bits 305 that is less than other subsets 310. In some examples, the subsets 310 other than the first subset 310-a and the last subset 310-d (e.g., a subset Iᵢ, where 1<i<n) may each contain a quantity of information bits 305 that is less than the quantity of information bits 305 of the first subset 310-a and greater than the quantity of information bits 305 of the last subset 310-d. In some cases, the quantity of information bits 305 for these subsets 310 may be the same.

The device may perform shaping (e.g., shaping bits calculation) of the first subset 310-a using a shaping decoder 315-a. For example, the device may generate a first set of shaping bits S₁ based on the first subset 310-a. The device may then generate a masking vector v₁ based on the first set of shaping bits S₁ using the shaping encoder 320-a. The device may mask the first subset 310-a using based on the masking vector v₁ and a mask block 325-a (e.g., an exclusive OR (XOR) block) to obtain a first set of shaped (e.g., masked) bits c₁.

The device may concatenate the second subset 310-b with the first set of shaping bits S₁ to obtain (e.g., generate) a first set of concatenated bits 330-a (e.g., I₂, S₁). The device may then perform shaping of the first set of concatenated bits 330-a using a shaping decoder 315-b. For example, the device may generate a second set of shaping bits S₂ based on the first set of concatenated bits 330-a (e.g., I₂, S₁). The device may then generate a masking vector v₂ based on the first set of shaping bits S₂ using the shaping encoder 320-b. The device may mask the first set of concatenated bits 330-a (e.g., I₂, S₁) based on the masking vector v₂ and a using a mask block 325-b (e.g., an XOR block) to obtain a second set of shaped (e.g., masked) bits c₂.

The device may perform a similar process to perform shaping associated with the third subset 310-c. For example, the device may concatenate the third subset 310-c with the second set of shaping bits S₂ to obtain (e.g., generate) a second set of concatenated bits 330-b (e.g., I₃, S₂). Then, the device may use a shaping decoder 315, a shaping encoder 320, and a mask block 325 to obtain a third set of shaped (e.g., masked) bits c₃ (not shown). Similarly, the device may iteratively continue this process for each subset 310 until and including the second-to-last subset (e.g., subset n−1).

To perform shaping associated with the last subset 310-d, the device may employ a self-contained shaping process. For example, the device concatenate the last subset 310-d with the second-to-last set of shaping bits Sₙ₋₁ to obtain (e.g., generate) a second-to-last set (e.g., set n−1) of concatenated bits (e.g., Iₙ, Sₙ₋₁). The device may generate a last set of shaping bits Sₙ based on the second-to-last set of concatenated bits 330-c (e.g., Iₙ, Sₙ₋₁) using a shaping decoder 315-c. The device may then generate a masking vector vₙ based on the last set of shaping bits Sₙ using the shaping encoder 320-c. The device may mask the first set of concatenated bits 330-c (e.g., Iₙ, Sₙ₋₁) based on the masking vector vₙ and a using a mask block 325-c (e.g., an XOR block) to obtain a last set of shaped (e.g., masked) bits cₙ. The device may concatenate the last set of shaped bits cₙ with the last set of shaping bits Sₙ to obtain a last set of concatenated bits 330-d.

In some examples, the device may perform steps associated with shaping encoder 320-a, shaping encoder 320-b, and shaping encoder 320-c using a single shaping encoder 320. For example, although FIG. 3 depicts multiple shaping encoders 320, the device may contain a single shaping encoder 320 that may perform steps associated with each of the shaping encoders 320, as described herein. Similarly, in some examples, the device may perform steps associated with shaping decoder 315-a, shaping decoder 315-b, and shaping decoder 315-c using a single shaping decoder 315.

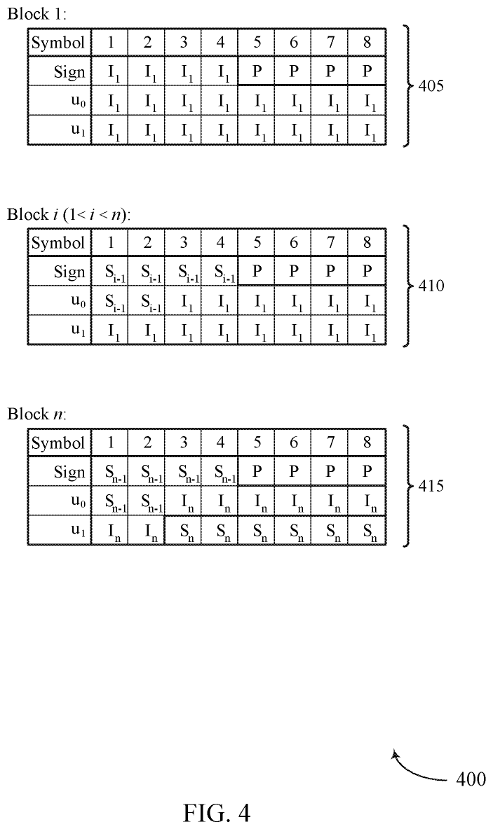

The device may encode each of the sets of shaped bits and the last set of shaping bits Sₙ using an encoder 335 (e.g., a joint FEC encoder). The encoder 335 may output a set of parity bits p. associated with each of the sets of shaped bits and the last set of shaping bits Sₙ. In some examples, the device may perform bit-to-symbol mapping 340 for each of the sets of shaped bits, the last set of shaping bits Sₙ, and the set of parity bits p. Examples related to the bit-to-symbol mapping 340 are described in further detail herein, with reference to FIG. 4.

Accordingly, the device may perform bit shaping in a serial manner that may reduce the quantity of unknown bits by concatenating the shaping bits with a next subset 310, which may have a smaller quantity of information bits than the current subset 310, and therefore avoid performance degradation associated with unknown LLR values.

FIG. 4 illustrates an example of a mapping scheme 400 that supports shaping code using serial processing in accordance with one or more aspects of the present disclosure. The mapping scheme 400 may support techniques to perform serial shaping of information bits in a transmission. For example, the mapping scheme 400 may support techniques for a device to perform bit-to-symbol mapping following a serial bit shaping process, as described herein with reference to FIG. 3. For example, the mapping scheme 400 may illustrate a block 405, a block 410, and a block 415, which may illustrate examples of bit-to-symbol mapping.

Each of the block 405, the block 410, and the block 415 may include multiple symbols. For each of the symbols, the block 405, the block 410, and the block 415 may include a sign bit, and one or more bits corresponding to a respective bit vectors (e.g., u₀ and u₁). While eight symbols and two bit vectors are illustrated, different quantities of symbols and bit vectors may be considered without departing from the scope of the present disclosure.

The block 405, the block 410, and the block 415 may each include one or more parity bits P. For example, the device may generate parity bits corresponding to a concatenation of all shaped bits and shaping bits for a transmission, as described herein, with reference to FIG. 3. The device may place the parity bits in sections allocated (e.g., pre-allocated) to the parity bits. In some examples and as illustrated herein, the device may place the parity bits as sign bits corresponding to symbols five through eight of each of the blocks 405, the block 410, and the block 415.

In some examples, the block 405 may represent a bit-to-symbol mapping performed by a device for a first subset of information bits for a transmission. In some examples, the block 405 may include a larger quantity of information bits I than other blocks, such as the block 410 and the block 415. For example, the first subset of the information bits may include 20 information bits I₁, which may each be included in block 405. However, other quantities of information bits I₁ are possible. As illustrated, one or more of the information bits I₁ may be included as part of the sign bits of block 405, for example, corresponding to symbols one through four.

In some examples, the block 410 may represent a bit-to-symbol mapping performed by a device for any of a second subset of the information bits to a second-to-last subset of the information bits for the transmission. For example, the block 410 may correspond to a subset i, where 1<i<n and the first subset is subset corresponds to a value of i=1. In some examples, the block 410 may include a smaller quantity of information bits I than the block 405 and a larger quantity of information bits I than the block 410. For example, one or more of the subsets between (and including) the second subset of the information bits and the second-to-last subset of the information bits may include 14 information bits Iᵢ. However, other quantities of information bits Iᵢ are possible. The block 410 may include shaping bits S associated with a previous subset of the information bits (e.g., a subset i−1). For example, the block 410 may include six shaping bits Sᵢ₋₁. However, other quantities of shaping bits Sᵢ₋₁ are possible. As illustrated, the shaping bits Sᵢ₋₁ may be included as part of the sign bits of block 410, for example, corresponding to symbols one through four, and as part of one or more of the bit vectors, such as u₀.

In some examples, the block 415 may represent a bit-to-symbol mapping performed by a device for a last subset of the information bits associated with the transmission. In some examples, the block 415 may include a smaller quantity of information bits I than other blocks, such as the block 405 and the block 415. For example, the last subset of the information bits may include eight information bits Iₙ. However, other quantities of information bits Iₙ are possible. In a similar manner as the block 410, the block 415 may include shaping bits S associated with a previous subset of the information bits (e.g., a subset n−1). For example, the block 410 may include six shaping bits Sₙ₋₁, though other quantities of shaping bits Sₙ₋₁ are possible. As illustrated, the shaping bits Sᵢ₋₁ may be included as part of the sign bits of block 415, for example, corresponding to symbols one through four, and as part of one or more of the bit vectors, such as u₀. Additionally, the block 415 may include shaping bits Sₙ associated with the shaping of the last subset of the information bits. In some examples, as the last subset of the information bits may include a smaller quantity of information bits Iₙ, the block 415 may have space allocated for the shaping bits Sₙ.

Accordingly, the device may include shaping bits S in the block 410 and the block 415 for each of the subsets of the information bits without resulting in unknown information bits I. This may reduce performance degradation associated with generating unknown LLR due to unknown information bits.

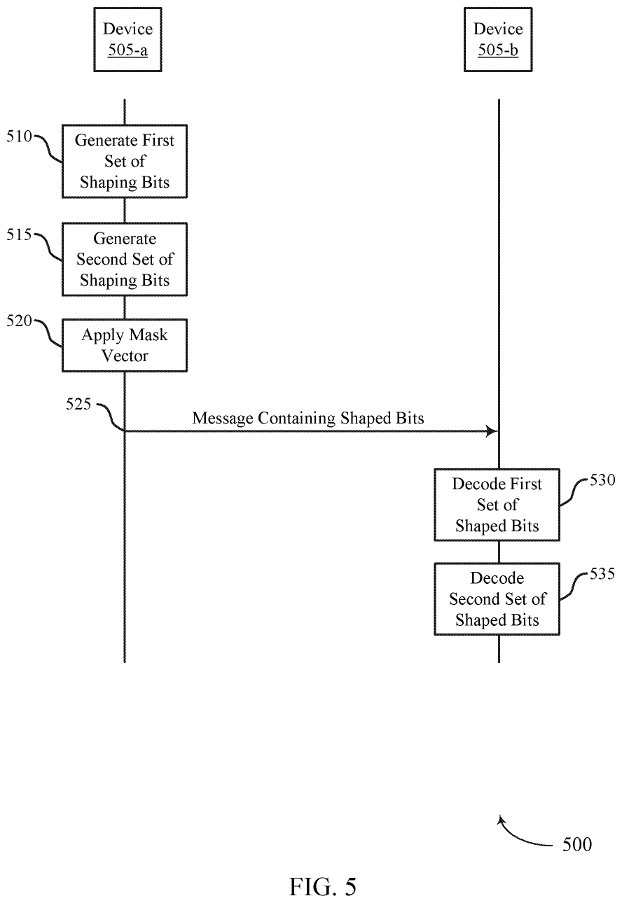

FIG. 5 illustrates an example of a process flow 500 that supports shaping code using serial processing in accordance with one or more aspects of the present disclosure. The process flow 500 may support techniques for a device 505-a to shape information bits and communicate with a device 505-b, which may be an example of devices and concepts as described herein, with reference to FIGS. 1 through 4. In the following description of the process flow 500, the operations performed by the device 505-a and the device 505-b may be performed in different orders or at different times. Additionally, or alternatively, some operations may be omitted from the process flow 500, and other operations may be added to the process flow 500.

At 510, the device 505-a may generate, using a first decoder, a first set of shaping bits associated with a first subset of a set of information bits. The set of information bits may correspond to a message to be transmitted from the device 505-a to the device 505-b. In some examples, generating the first set of shaping bits may be based on one or more (e.g., generated) LLR values.

At 515, the device 505-a may generate, using a second decoder, a second set of shaping bits associated with a first set of concatenated bits. The first set of concatenated bits may correspond to a concatenation of a second subset of the set of information bits and the first set of shaping bits. In some examples, generating the second set of shaping bits may be based on one or more (e.g., generated) LLR values.

In some examples, the device 505-a may generate additional sets of shaping bits associated with additional sets of concatenated bits. For example, the device 505-a may generate, using a third decoder of the first device, a third set of shaping bits based on a second set of concatenated bits. The second set of concatenated bits may correspond to a concatenation of the second set of shaping bits and a third subset of the set of information bits.

In some examples, the quantity of bits of the first subset of the set of information bits may be greater than the quantity of bits of the second subset of the set of information bits. Similarly, the quantity of bits of the first subset of the set of information bits may be greater than the quantity of bits of the third subset of the set of information bits. In some cases, the quantity of bits of the third subset of the set of information bits may be smaller than the quantity of bits of the second subset of the set of information bits.

At 520, the device 505-a may apply a second mask vector to the first set of concatenated bits using a first encoder of the device 505-a. The masking may result in a second set of shaped bits. In some examples, the device 505-a may apply a first mask vector to the first subset of the set of information bits using a first encoder of the device 505-a to obtain a first set of shaped bits. In some cases, the device 505-a may generate, using a third encoder (e.g., an FEC encoder) of the device 505-a, a set of parity bits based on the first set of shaped bits, the second set of shaped bits, and the second set of shaping bits. In some examples, applying the second mask vector, or performing bit shaping, may be based on determining that transmitting the message including at least the second set of shaped bits consumes less power than a transmission including the second subset of the set of information bits (e.g., un-shaped or unmasked).

In some examples, the device 505-a may apply additional mask vectors to additional sets of concatenated bits to generate additional sets of shaped bits based on additional sets of shaping bits. For example, the device 505-a may apply a third mask vector to the second set of concatenated bits using a second encoder of the device 505-a to obtain a third set of shaped bits. In these examples, the generation of the set of parity bits may be based on the additional sets of shaped bits and shaping bits.

At 525, the device 505-a may transmit a message to the device 505-b that includes the second set of shaped bits. In some examples, the message may further include additional sets of shaped bits, such as the first set of shaped bits. In some cases, the message may additionally include the set of parity bits. In some cases, the device 505-a may map the sets of shaped bits, the parity bits, the shaping bits, or a combination thereof, to one or more symbols prior to the transmission to obtain a set of mapped bits, and the transmission may be based on the mapping.

At 530, the device 505-b may decode a first set of received shaped bits based on the first set of received shaping bits to obtain a last set of information bits and a second set of received shaping bits. The first set of received shaped bits may correspond to a last set of shaped bits of the message. Similarly, the first set of received shaping bits may correspond to a last set of shaping bits of the message, while the second set of received shaping bits may correspond to a second-to-last set of shaping bits of the message. Accordingly, the device 505-b may perform decoding of the shaping bits beginning from the last set of shaped bits included in the message, as a last block of the message may contain the last set of shaped bits (e.g., the first set of received shaped bits) and the last set of shaping bits used for decoding the last set of shaped bits. In some examples, decoding the first set of received shaped bits may be based on the one or more parity bits included in the message.

At 535, the device 505-b may decode a second set of received shaped bits based on the second set of received shaping bits. The second set of received shaping bits may be based on the decoding the first set of received shaped bits. The decoding of the second set of received shaped bits may output a second-to-last subset of the set of information blocks. If the second-to-last subset corresponds to a subset other than the first subset (i.e., if there are more than two subsets), then the decoding of the second set of received shaped bits may also output a third set of received shaping bits (e.g., corresponding to a third-to-last set of shaping bits included in the message). In some examples, decoding the second set of received shaped bits may be based on the one or more parity bits included in the message.

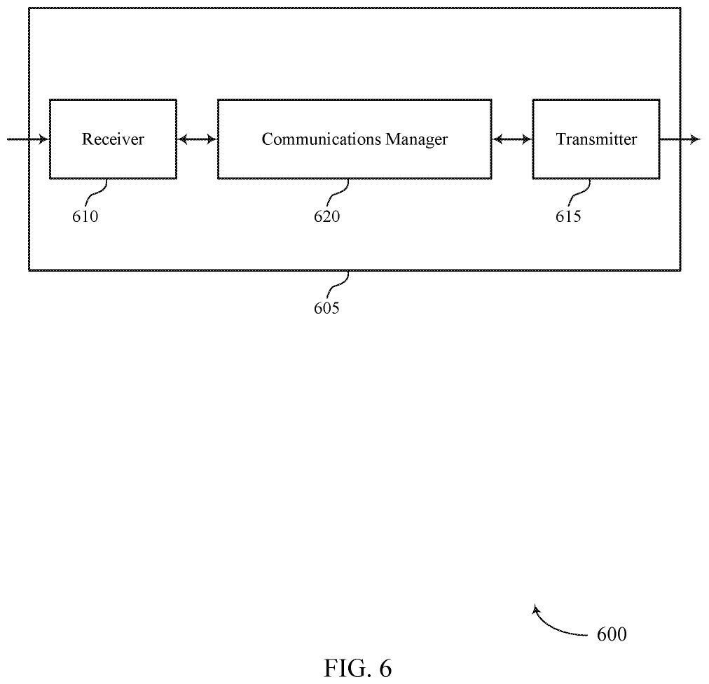

FIG. 6 shows a block diagram 600 of a device 605 that supports shaping code using serial processing in accordance with one or more aspects of the present disclosure. The device 605 may be an example of aspects of a UE 115 or a network entity 105 as described herein. The device 605 may include a receiver 610, a transmitter 615, and a communications manager 620. The device 605 may also include a processor. Each of these components may be in communication with one another (e.g., via one or more buses).

The receiver 610 may provide a means for receiving information such as packets, user data, control information, or any combination thereof associated with various information channels (e.g., control channels, data channels, information channels related to shaping code using serial processing). Information may be passed on to other components of the device 605. The receiver 610 may utilize a single antenna or a set of multiple antennas.

The transmitter 615 may provide a means for transmitting signals generated by other components of the device 605. For example, the transmitter 615 may transmit information such as packets, user data, control information, or any combination thereof associated with various information channels (e.g., control channels, data channels, information channels related to shaping code using serial processing). In some examples, the transmitter 615 may be co-located with a receiver 610 in a transceiver module. The transmitter 615 may utilize a single antenna or a set of multiple antennas.

The communications manager 620, the receiver 610, the transmitter 615, or various combinations thereof or various components thereof may be examples of means for performing various aspects of shaping code using serial processing as described herein. For example, the communications manager 620, the receiver 610, the transmitter 615, or various combinations or components thereof may support a method for performing one or more of the functions described herein.

In some examples, the communications manager 620, the receiver 610, the transmitter 615, or various combinations or components thereof may be implemented in hardware (e.g., in communications management circuitry). The hardware may include a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting a means for performing the functions described in the present disclosure. In some examples, a processor and memory coupled with the processor may be configured to perform one or more of the functions described herein (e.g., by executing, by the processor, instructions stored in the memory).

Additionally, or alternatively, in some examples, the communications manager 620, the receiver 610, the transmitter 615, or various combinations or components thereof may be implemented in code (e.g., as communications management software or firmware) executed by a processor. If implemented in code executed by a processor, the functions of the communications manager 620, the receiver 610, the transmitter 615, or various combinations or components thereof may be performed by a general-purpose processor, a DSP, a CPU, an ASIC, an FPGA, a microcontroller, or any combination of these or other programmable logic devices (e.g., configured as or otherwise supporting a means for performing the functions described in the present disclosure).

In some examples, the communications manager 620 may be configured to perform various operations (e.g., receiving, obtaining, monitoring, outputting, transmitting) using or otherwise in cooperation with the receiver 610, the transmitter 615, or both. For example, the communications manager 620 may receive information from the receiver 610, send information to the transmitter 615, or be integrated in combination with the receiver 610, the transmitter 615, or both to obtain information, output information, or perform various other operations as described herein.

The communications manager 620 may support wireless communications at a first device in accordance with examples as disclosed herein. For example, the communications manager 620 may be configured as or otherwise support a means for generating, using a first decoder of the first device, a first set of shaping bits associated with a first subset of a set of information bits. The communications manager 620 may be configured as or otherwise support a means for generating, using a second decoder of the first device, a second set of shaping bits based on a first set of concatenated bits including at least the first set of shaping bits and a second subset of the set of information bits. The communications manager 620 may be configured as or otherwise support a means for applying a second mask vector to the first set of concatenated bits based on a first encoder of the first device to obtain a second set of shaped bits. The communications manager 620 may be configured as or otherwise support a means for transmitting, based on applying the second mask vector, a message including at least the second set of shaped bits.

Additionally, or alternatively, the communications manager 620 may support wireless communications at a second device in accordance with examples as disclosed herein. For example, the communications manager 620 may be configured as or otherwise support a means for receiving a message including a set of multiple shaped bits and a first set of shaping bits, the set of multiple shaped bits including at least a first set of shaped bits and a second set of shaped bits. The communications manager 620 may be configured as or otherwise support a means for decoding, based on the first set of shaping bits, the first set of shaped bits to obtain a first set of information bits and a second set of shaping bits. The communications manager 620 may be configured as or otherwise support a means for decoding, based on the second set of shaping bits, the second set of shaped bits to obtain a second set of information bits.

By including or configuring the communications manager 620 in accordance with examples as described herein, the device 605 (e.g., a processor controlling or otherwise coupled with the receiver 610, the transmitter 615, the communications manager 620, or a combination thereof) may support techniques for bit shaping using serial processing that reduces performance degradation due to unknown information bits, which may improve performance and reliability of transmissions.

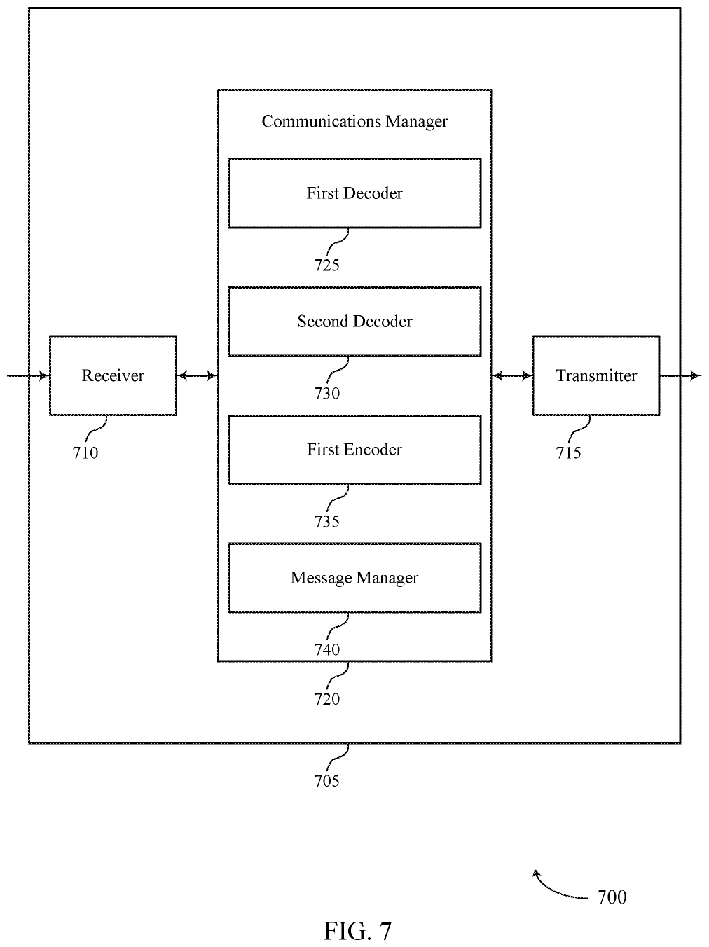

FIG. 7 shows a block diagram 700 of a device 705 that supports shaping code using serial processing in accordance with one or more aspects of the present disclosure. The device 705 may be an example of aspects of a device 605, a UE 115, or a network entity 105 as described herein. The device 705 may include a receiver 710, a transmitter 715, and a communications manager 720. The device 705 may also include a processor. Each of these components may be in communication with one another (e.g., via one or more buses).

The receiver 710 may provide a means for receiving information such as packets, user data, control information, or any combination thereof associated with various information channels (e.g., control channels, data channels, information channels related to shaping code using serial processing). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (e.g., control channels, data channels, information channels related to shaping code using serial processing). In some examples, the transmitter 715 may be co-located with a receiver 710 in a transceiver module. The transmitter 715 may utilize a single antenna or a set of multiple antennas.

The device 705, or various components thereof, may be an example of means for performing various aspects of shaping code using serial processing as described herein. For example, the communications manager 720 may include a first decoder 725, a second decoder 730, a first encoder 735, a message manager 740, or any combination thereof. The communications manager 720 may be an example of aspects of a communications manager 620 as described herein. In some examples, the communications manager 720, or various components thereof, may be configured to perform various operations (e.g., receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communications at a first device in accordance with examples as disclosed herein. The first decoder 725 may be configured as or otherwise support a means for generating, using a first decoder of the first device, a first set of shaping bits associated with a first subset of a set of information bits. The second decoder 730 may be configured as or otherwise support a means for generating, using a second decoder of the first device, a second set of shaping bits based on a first set of concatenated bits including at least the first set of shaping bits and a second subset of the set of information bits. The first encoder 735 may be configured as or otherwise support a means for applying a second mask vector to the first set of concatenated bits based on a first encoder of the first device to obtain a second set of shaped bits. The message manager 740 may be configured as or otherwise support a means for transmitting, based on applying the second mask vector, a message including at least the second set of shaped bits.

Additionally, or alternatively, the communications manager 720 may support wireless communications at a second device in accordance with examples as disclosed herein. The message manager 740 may be configured as or otherwise support a means for receiving a message including a set of multiple shaped bits and a first set of shaping bits, the set of multiple shaped bits including at least a first set of shaped bits and a second set of shaped bits. The first decoder 725 may be configured as or otherwise support a means for decoding, based on the first set of shaping bits, the first set of shaped bits to obtain a first set of information bits and a second set of shaping bits. The second decoder 730 may be configured as or otherwise support a means for decoding, based on the second set of shaping bits, the second set of shaped bits to obtain a second set of information bits.

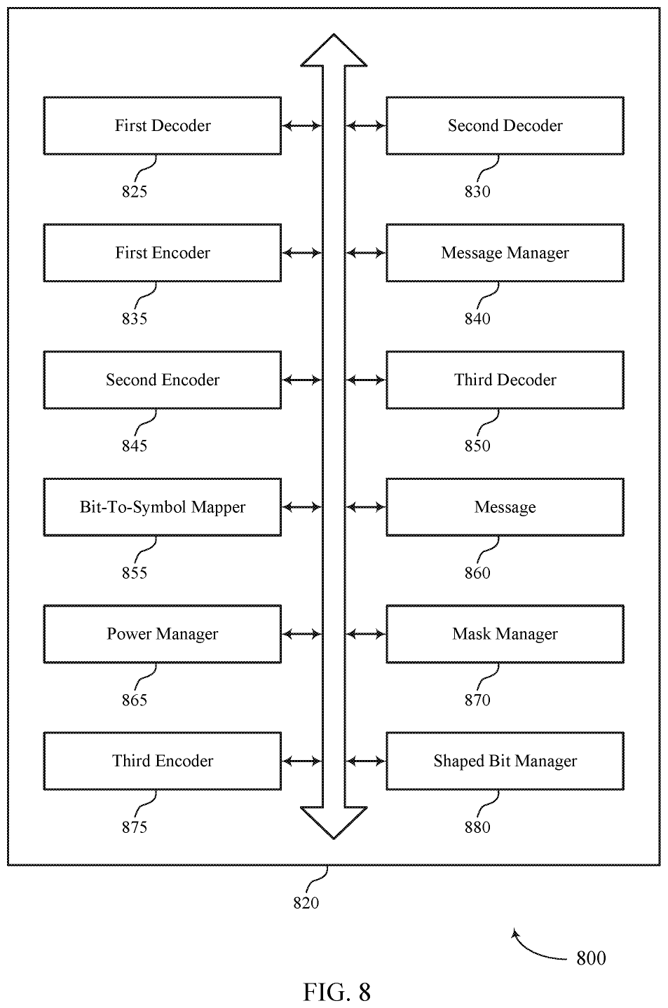

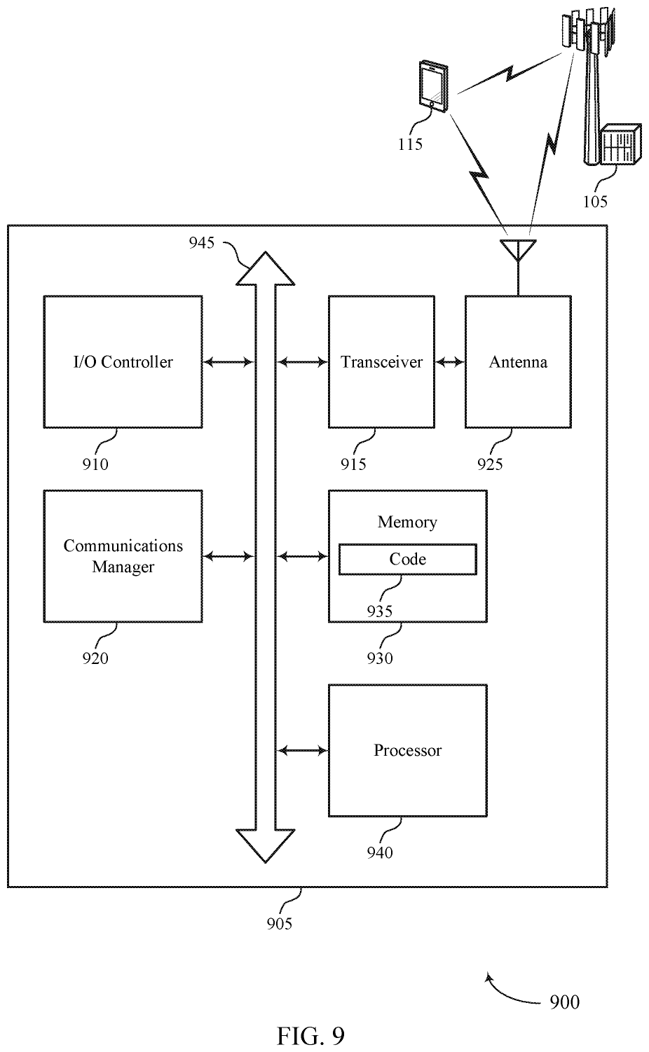

FIG. 8 shows a block diagram 800 of a communications manager 820 that supports shaping code using serial processing in accordance with one or more aspects of the present disclosure. The communications manager 820 may be an example of aspects of a communications manager 620, a communications manager 720, or both, as described herein. The communications manager 820, or various components thereof, may be an example of means for performing various aspects of shaping code using serial processing as described herein. For example, the communications manager 820 may include a first decoder 825, a second decoder 830, a first encoder 835, a message manager 840, a second encoder 845, a third decoder 850, a bit-to-symbol mapper 855, a message 860, a power manager 865, a mask manager 870, a third encoder 875, a shaped bit manager 880, or any combination thereof. Each of these components may communicate, directly or indirectly, with one another (e.g., via one or more buses) which may include communications within a protocol layer of a protocol stack, communications associated with a logical channel of a protocol stack (e.g., between protocol layers of a protocol stack, within a device, component, or virtualized component associated with a network entity 105, between devices, components, or virtualized components associated with a network entity 105), or any combination thereof.

The communications manager 820 may support wireless communications at a first device in accordance with examples as disclosed herein. The first decoder 825 may be configured as or otherwise support a means for generating, using a first decoder of the first device, a first set of shaping bits associated with a first subset of a set of information bits. The second decoder 830 may be configured as or otherwise support a means for generating, using a second decoder of the first device, a second set of shaping bits based on a first set of concatenated bits including at least the first set of shaping bits and a second subset of the set of information bits. The first encoder 835 may be configured as or otherwise support a means for applying a second mask vector to the first set of concatenated bits based on a first encoder of the first device to obtain a second set of shaped bits. The message manager 840 may be configured as or otherwise support a means for transmitting, based on applying the second mask vector, a message including at least the second set of shaped bits.

In some examples, the second encoder 845 may be configured as or otherwise support a means for applying a first mask vector to the first subset of the set of information bits based on the first encoder of the first device to obtain a first set of shaped bits, where the message further includes the first set of shaped bits.

In some examples, the third encoder 875 may be configured as or otherwise support a means for generating, using a third encoder of the first device, a set of parity bits based on the first set of shaped bits, the second set of shaped bits, and the second set of shaping bits, where the message further includes the set of parity bits.

In some examples, the third decoder 850 may be configured as or otherwise support a means for generating, using a third decoder of the first device, a third set of shaping bits based on a second set of concatenated bits, the second set of concatenated bits including at least the second set of shaping bits and a third subset of the set of information bits.

In some examples, the second encoder 845 may be configured as or otherwise support a means for applying a third mask vector to the second set of concatenated bits based on a second encoder of the first device to obtain a third set of shaped bits. In some examples, the shaped bit manager 880 may be configured as or otherwise support a means for generating a third set of concatenated bits including at least the second set of shaped bits and the third set of shaping bits, where the message further includes the third set of concatenated bits.

In some examples, the third encoder 875 may be configured as or otherwise support a means for generating, using a third encoder of the first device, a set of parity bits based on the third set of concatenated bits, the second set of shaped bits, and the first subset of the set of information bits, where the message further includes the set of parity bits. In some examples, a quantity of bits of the first subset of the set of information bits is greater than a quantity of bits of the third subset of the set of information bits.

In some examples, to support transmitting the message, the bit-to-symbol mapper 855 may be configured as or otherwise support a means for mapping the second set of shaped bits to one or more symbols to obtain a set of mapped bits. In some examples, to support transmitting the message, the message 860 may be configured as or otherwise support a means for transmitting, based on applying the second mask vector and on the mapping, a message including at least the set of mapped bits.

In some examples, to support generating the first set of shaping bits, the first decoder 825 may be configured as or otherwise support a means for generating, using the first decoder of the first device, the first set of shaping bits associated with the first subset of the set of information bits based on one or more log-likelihood ratio values.

In some examples, the power manager 865 may be configured as or otherwise support a means for determining that transmitting the message including at least the second set of shaped bits consumes less power than a transmission including the second subset of the set of information bits, where applying the second mask vector is based on the message consuming less power than the transmission. In some examples, a quantity of bits of the first subset of the set of information bits is greater than a quantity of bits of the second subset of the set of information bits.

Additionally, or alternatively, the communications manager 820 may support wireless communications at a second device in accordance with examples as disclosed herein. In some examples, the message manager 840 may be configured as or otherwise support a means for receiving a message including a set of multiple shaped bits and a first set of shaping bits, the set of multiple shaped bits including at least a first set of shaped bits and a second set of shaped bits. In some examples, the first decoder 825 may be configured as or otherwise support a means for decoding, based on the first set of shaping bits, the first set of shaped bits to obtain a first set of information bits and a second set of shaping bits. In some examples, the second decoder 830 may be configured as or otherwise support a means for decoding, based on the second set of shaping bits, the second set of shaped bits to obtain a second set of information bits.

In some examples, to support decoding the second set of shaped bits, the second decoder 830 may be configured as or otherwise support a means for decoding, based on the second set of shaping bits, the second set of shaped bits to obtain the second set of information bits and a third set of shaping bits.

In some examples, the third decoder 850 may be configured as or otherwise support a means for decoding, based on the third set of shaping bits, the third set of shaped bits to obtain a third set of information bits. In some examples, a quantity of bits of the third set of information bits is greater than a quantity of bits of the second set of information bits.

In some examples, to support decoding the first set of shaped bits, the mask manager 870 may be configured as or otherwise support a means for applying a mask vector to the first set of shaped bits to obtain the first set of information bits and the second set of shaping bits, where the mask vector is based on the first set of shaping bits. In some examples, a quantity of bits of the second set of information bits is greater than a quantity of bits of the first set of information bits.

In some examples, the bit-to-symbol mapper 855 may be configured as or otherwise support a means for mapping the set of multiple shaped bits and the first set of shaping bits to one or more symbols, where decoding the first set of shaped bits is based on the mapping.

In some examples, the message further includes a set of parity bits.

FIG. 9 shows a diagram of a system 900 including a device 905 that supports shaping code using serial processing in accordance with one or more aspects of the present disclosure. The device 905 may be an example of or include the components of a device 605, a device 705, or a UE 115 as described herein. The device 905 may communicate (e.g., wirelessly) with one or more network entities 105, one or more UEs 115, or any combination thereof. The device 905 may include components for bi-directional voice and data communications including components for transmitting and receiving communications, such as a communications manager 920, an input/output (I/O) controller 910, a transceiver 915, an antenna 925, a memory 930, code 935, and a processor 940. These components may be in electronic communication or otherwise coupled (e.g., operatively, communicatively, functionally, electronically, electrically) via one or more buses (e.g., a bus 945).

The I/O controller 910 may manage input and output signals for the device 905. The I/O controller 910 may also manage peripherals not integrated into the device 905. In some cases, the I/O controller 910 may represent a physical connection or port to an external peripheral. In some cases, the I/O controller 910 may utilize an operating system such as iOS®, ANDROID®, MS-DOS®, MS-WINDOWS®, OS/2®, UNIX®, LINUX®, or another known operating system. Additionally, or alternatively, the I/O controller 910 may represent or interact with a modem, a keyboard, a mouse, a touchscreen, or a similar device. In some cases, the I/O controller 910 may be implemented as part of a processor, such as the processor 940. In some cases, a user may interact with the device 905 via the I/O controller 910 or via hardware components controlled by the I/O controller 910.

In some cases, the device 905 may include a single antenna 925. However, in some other cases, the device 905 may have more than one antenna 925, which may be capable of concurrently transmitting or receiving multiple wireless transmissions. The transceiver 915 may communicate bi-directionally, via the one or more antennas 925, wired, or wireless links as described herein. For example, the transceiver 915 may represent a wireless transceiver and may communicate bi-directionally with another wireless transceiver. The transceiver 915 may also include a modem to modulate the packets, to provide the modulated packets to one or more antennas 925 for transmission, and to demodulate packets received from the one or more antennas 925. The transceiver 915, or the transceiver 915 and one or more antennas 925, may be an example of a transmitter 615, a transmitter 715, a receiver 610, a receiver 710, or any combination thereof or component thereof, as described herein.

The memory 930 may include random access memory (RAM) and read-only memory (ROM). The memory 930 may store computer-readable, computer-executable code 935 including instructions that, when executed by the processor 940, cause the device 905 to perform various functions described herein. The code 935 may be stored in a non-transitory computer-readable medium such as system memory or another type of memory. In some cases, the code 935 may not be directly executable by the processor 940 but may cause a computer (e.g., when compiled and executed) to perform functions described herein. In some cases, the memory 930 may contain, among other things, a basic I/O system (BIOS) which may control basic hardware or software operation such as the interaction with peripheral components or devices.

The processor 940 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 940 may be configured to operate a memory array using a memory controller. In some other cases, a memory controller may be integrated into the processor 940. The processor 940 may be configured to execute computer-readable instructions stored in a memory (e.g., the memory 930) to cause the device 905 to perform various functions (e.g., functions or tasks supporting shaping code using serial processing). For example, the device 905 or a component of the device 905 may include a processor 940 and memory 930 coupled with or to the processor 940, the processor 940 and memory 930 configured to perform various functions described herein.

The communications manager 920 may support wireless communications at a first device in accordance with examples as disclosed herein. For example, the communications manager 920 may be configured as or otherwise support a means for generating, using a first decoder of the first device, a first set of shaping bits associated with a first subset of a set of information bits. The communications manager 920 may be configured as or otherwise support a means for generating, using a second decoder of the first device, a second set of shaping bits based on a first set of concatenated bits including at least the first set of shaping bits and a second subset of the set of information bits. The communications manager 920 may be configured as or otherwise support a means for applying a second mask vector to the first set of concatenated bits based on a first encoder of the first device to obtain a second set of shaped bits. The communications manager 920 may be configured as or otherwise support a means for transmitting, based on applying the second mask vector, a message including at least the second set of shaped bits.

Additionally, or alternatively, the communications manager 920 may support wireless communications at a second device in accordance with examples as disclosed herein. For example, the communications manager 920 may be configured as or otherwise support a means for receiving a message including a set of multiple shaped bits and a first set of shaping bits, the set of multiple shaped bits including at least a first set of shaped bits and a second set of shaped bits. The communications manager 920 may be configured as or otherwise support a means for decoding, based on the first set of shaping bits, the first set of shaped bits to obtain a first set of information bits and a second set of shaping bits. The communications manager 920 may be configured as or otherwise support a means for decoding, based on the second set of shaping bits, the second set of shaped bits to obtain a second set of information bits.

By including or configuring the communications manager 920 in accordance with examples as described herein, the device 905 may support techniques for bit shaping using serial processing that reduces performance degradation due to unknown information bits, which may improve performance and reliability of transmissions.

In some examples, the communications manager 920 may be configured to perform various operations (e.g., receiving, monitoring, transmitting) using or otherwise in cooperation with the transceiver 915, the one or more antennas 925, or any combination thereof. Although the communications manager 920 is illustrated as a separate component, in some examples, one or more functions described with reference to the communications manager 920 may be supported by or performed by the processor 940, the memory 930, the code 935, or any combination thereof. For example, the code 935 may include instructions executable by the processor 940 to cause the device 905 to perform various aspects of shaping code using serial processing as described herein, or the processor 940 and the memory 930 may be otherwise configured to perform or support such operations.

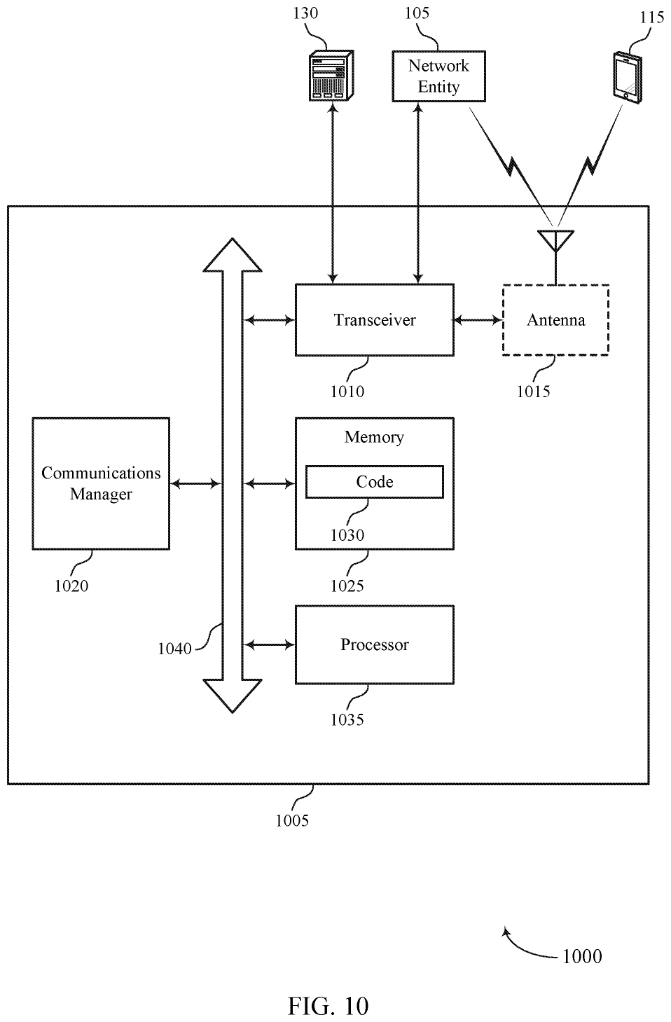

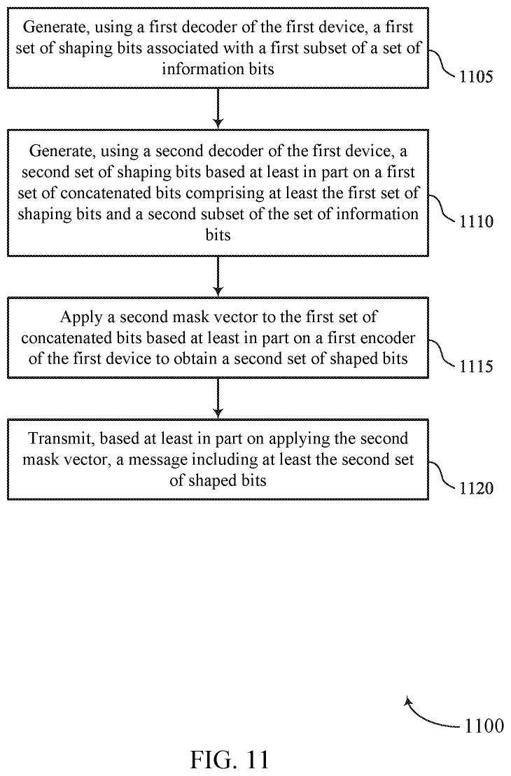

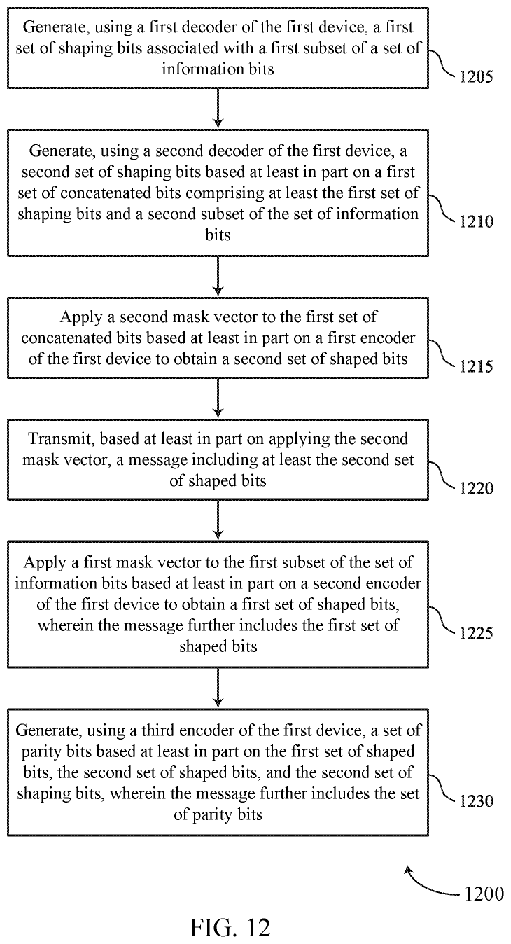

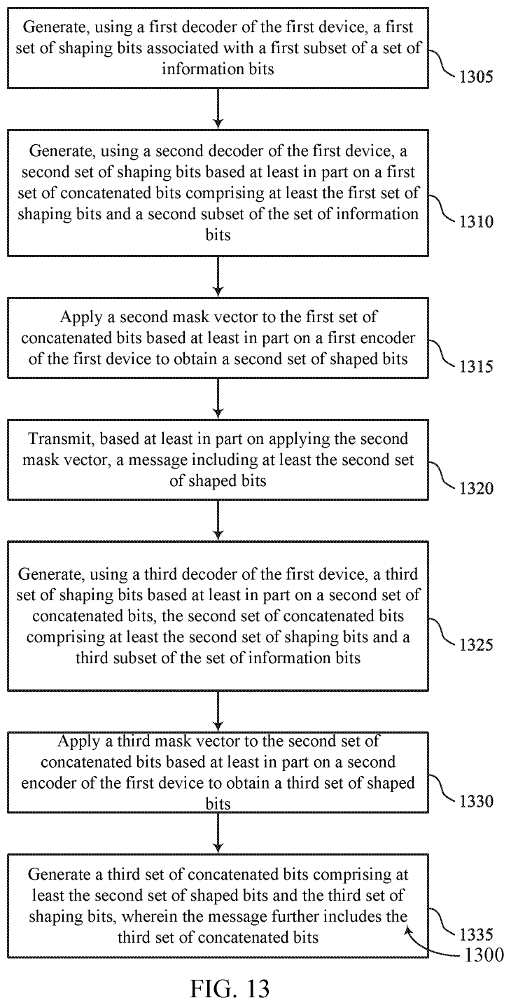

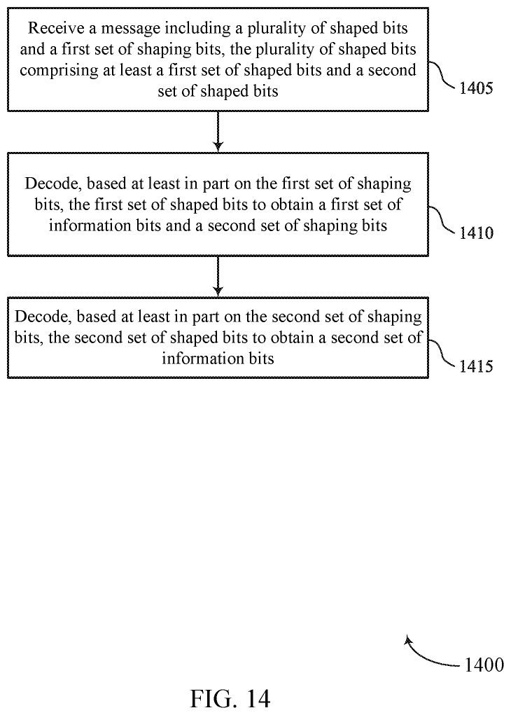

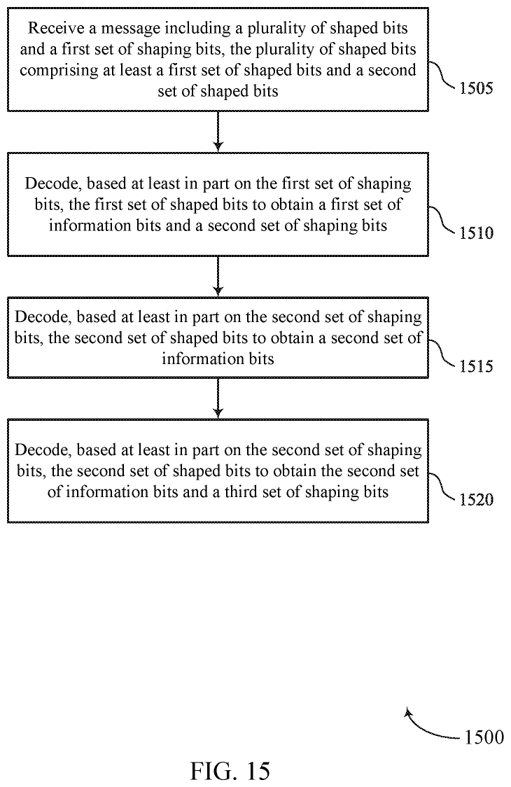

FIG. 10 shows a diagram of a system 1000 including a device 1005 that supports shaping code using serial processing in accordance with one or more aspects of the present disclosure. The device 1005 may be an example of or include the components of a device 605, a device 705, or a network entity 105 as described herein. The device 1005 may communicate with one or more network entities 105, one or more UEs 115, or any combination thereof, which may include communications over one or more wired interfaces, over one or more wireless interfaces, or any combination thereof. The device 1005 may include components that support outputting and obtaining communications, such as a communications manager 1020, a transceiver 1010, an antenna 1015, a memory 1025, code 1030, and a processor 1035. These components may be in electronic communication or otherwise coupled (e.g., operatively, communicatively, functionally, electronically, electrically) via one or more buses (e.g., a bus 1040).

The transceiver 1010 may support bi-directional communications via wired links, wireless links, or both as described herein. In some examples, the transceiver 1010 may include a wired transceiver and may communicate bi-directionally with another wired transceiver. Additionally, or alternatively, in some examples, the transceiver 1010 may include a wireless transceiver and may communicate bi-directionally with another wireless transceiver. In some examples, the device 1005 may include one or more antennas 1015, which may be capable of transmitting or receiving wireless transmissions (e.g., concurrently). The transceiver 1010 may also include a modem to modulate signals, to provide the modulated signals for transmission (e.g., by one or more antennas 1015, by a wired transmitter), to receive modulated signals (e.g., from one or more antennas 1015, from a wired receiver), and to demodulate signals. In some implementations, the transceiver 1010 may include one or more interfaces, such as one or more interfaces coupled with the one or more antennas 1015 that are configured to support various receiving or obtaining operations, or one or more interfaces coupled with the one or more antennas 1015 that are configured to support various transmitting or outputting operations, or a combination thereof. In some implementations, the transceiver 1010 may include or be configured for coupling with one or more processors or memory components that are operable to perform or support operations based on received or obtained information or signals, or to generate information or other signals for transmission or other outputting, or any combination thereof. In some implementations, the transceiver 1010, or the transceiver 1010 and the one or more antennas 1015, or the transceiver 1010 and the one or more antennas 1015 and one or more processors or memory components (for example, the processor 1035, or the memory 1025, or both), may be included in a chip or chip assembly that is installed in the device 1005. In some examples, the transceiver may be operable to support communications via one or more communications links (e.g., a communication link 125, a backhaul communication link 120, a midhaul communication link 162, a fronthaul communication link 168).

The memory 1025 may include RAM and ROM. The memory 1025 may store computer-readable, computer-executable code 1030 including instructions that, when executed by the processor 1035, cause the device 1005 to perform various functions described herein. The code 1030 may be stored in a non-transitory computer-readable medium such as system memory or another type of memory. In some cases, the code 1030 may not be directly executable by the processor 1035 but may cause a computer (e.g., when compiled and executed) to perform functions described herein. In some cases, the memory 1025 may contain, among other things, a BIOS which may control basic hardware or software operation such as the interaction with peripheral components or devices.

The processor 1035 may include an intelligent hardware device (e.g., a general-purpose processor, a DSP, an ASIC, a CPU, an FPGA, a microcontroller, a programmable logic device, discrete gate or transistor logic, a discrete hardware component, or any combination thereof). In some cases, the processor 1035 may be configured to operate a memory array using a memory controller. In some other cases, a memory controller may be integrated into the processor 1035. The processor 1035 may be configured to execute computer-readable instructions stored in a memory (e.g., the memory 1025) to cause the device 1005 to perform various functions (e.g., functions or tasks supporting shaping code using serial processing). For example, the device 1005 or a component of the device 1005 may include a processor 1035 and memory 1025 coupled with the processor 1035, the processor 1035 and memory 1025 configured to perform various functions described herein. The processor 1035 may be an example of a cloud-computing platform (e.g., one or more physical nodes and supporting software such as operating systems, virtual machines, or container instances) that may host the functions (e.g., by executing code 1030) to perform the functions of the device 1005. The processor 1035 may be any one or more suitable processors capable of executing scripts or instructions of one or more software programs stored in the device 1005 (such as within the memory 1025). In some implementations, the processor 1035 may be a component of a processing system. A processing system may generally refer to a system or series of machines or components that receives inputs and processes the inputs to produce a set of outputs (which may be passed to other systems or components of, for example, the device 1005). For example, a processing system of the device 1005 may refer to a system including the various other components or subcomponents of the device 1005, such as the processor 1035, or the transceiver 1010, or the communications manager 1020, or other components or combinations of components of the device 1005. The processing system of the device 1005 may interface with other components of the device 1005, and may process information received from other components (such as inputs or signals) or output information to other components. For example, a chip or modem of the device 1005 may include a processing system and one or more interfaces to output information, or to obtain information, or both. The one or more interfaces may be implemented as or otherwise include a first interface configured to output information and a second interface configured to obtain information, or a same interface configured to output information and to obtain information, among other implementations. In some implementations, the one or more interfaces may refer to an interface between the processing system of the chip or modem and a transmitter, such that the device 1005 may transmit information output from the chip or modem. Additionally, or alternatively, in some implementations, the one or more interfaces may refer to an interface between the processing system of the chip or modem and a receiver, such that the device 1005 may obtain information or signal inputs, and the information may be passed to the processing system. A person having ordinary skill in the art will readily recognize that a first interface also may obtain information or signal inputs, and a second interface also may output information or signal outputs.

In some examples, a bus 1040 may support communications of (e.g., within) a protocol layer of a protocol stack. In some examples, a bus 1040 may support communications associated with a logical channel of a protocol stack (e.g., between protocol layers of a protocol stack), which may include communications performed within a component of the device 1005, or between different components of the device 1005 that may be co-located or located in different locations (e.g., where the device 1005 may refer to a system in which one or more of the communications manager 1020, the transceiver 1010, the memory 1025, the code 1030, and the processor 1035 may be located in one of the different components or divided between different components).

In some examples, the communications manager 1020 may manage aspects of communications with a core network 130 (e.g., via one or more wired or wireless backhaul links). For example, the communications manager 1020 may manage the transfer of data communications for client devices, such as one or more UEs 115. In some examples, the communications manager 1020 may manage communications with other network entities 105, and may include a controller or scheduler for controlling communications with UEs 115 in cooperation with other network entities 105. In some examples, the communications manager 1020 may support an X2 interface within an LTE/LTE-A wireless communications network technology to provide communication between network entities 105.

The communications manager 1020 may support wireless communications at a first device in accordance with examples as disclosed herein. For example, the communications manager 1020 may be configured as or otherwise support a means for generating, using a first decoder of the first device, a first set of shaping bits associated with a first subset of a set of information bits. The communications manager 1020 may be configured as or otherwise support a means for generating, using a second decoder of the first device, a second set of shaping bits based on a first set of concatenated bits including at least the first set of shaping bits and a second subset of the set of information bits. The communications manager 1020 may be configured as or otherwise support a means for applying a second mask vector to the first set of concatenated bits based on a first encoder of the first device to obtain a second set of shaped bits. The communications manager 1020 may be configured as or otherwise support a means for transmitting, based on applying the second mask vector, a message including at least the second set of shaped bits.

Additionally, or alternatively, the communications manager 1020 may support wireless communications at a second device in accordance with examples as disclosed herein. For example, the communications manager 1020 may be configured as or otherwise support a means for receiving a message including a set of multiple shaped bits and a first set of shaping bits, the set of multiple shaped bits including at least a first set of shaped bits and a second set of shaped bits. The communications manager 1020 may be configured as or otherwise support a means for decoding, based on the first set of shaping bits, the first set of shaped bits to obtain a first set of information bits and a second set of shaping bits. The communications manager 1020 may be configured as or otherwise support a means for decoding, based on the second set of shaping bits, the second set of shaped bits to obtain a second set of information bits.

By including or configuring the communications manager 1020 in accordance with examples as described herein, the device 1005 may support techniques for bit shaping using serial processing that reduces performance degradation due to unknown information bits, which may improve performance and reliability of communications.

In some examples, the communications manager 1020 may be configured to perform various operations (e.g., receiving, obtaining, monitoring, outputting, transmitting) using or otherwise in cooperation with the transceiver 1010, the one or more antennas 1015 (e.g., where applicable), or any combination thereof. Although the communications manager 1020 is illustrated as a separate component, in some examples, one or more functions described with reference to the communications manager 1020 may be supported by or performed by the transceiver 1010, the processor 1035, the memory 1025, the code 1030, or any combination thereof. For example, the code 1030 may include instructions executable by the processor 1035 to cause the device 1005 to perform various aspects of shaping code using serial processing as described herein, or the processor 1035 and the memory 1025 may be otherwise configured to perform or support such operations.

FIG. 11 shows a flowchart illustrating a method 1100 that supports shaping code using serial processing in accordance with one or more aspects of the present disclosure. The operations of the method 1100 may be implemented by a UE or a network entity or its components as described herein. For example, the operations of the method 1100 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1105, the method may include generating, using a first decoder of the first device, a first set of shaping bits associated with a first subset of a set of information bits. The operations of 1105 may be performed in accordance with examples as disclosed herein. In some examples, aspects of the operations of 1105 may be performed by a first decoder 825 as described with reference to FIG. 8.

At 1110, the method may include generating, using a second decoder of the first device, a second set of shaping bits based on a first set of concatenated bits including at least the first set of shaping bits and a second subset of the set of information bits. The operations of 1110 may be performed in accordance with examples as disclosed herein. In some examples, aspects of the operations of 1110 may be performed by a second decoder 830 as described with reference to FIG. 8.

At 1115, the method may include applying a second mask vector to the first set of concatenated bits based on a first encoder of the first device to obtain a second set of shaped bits. The operations of 1115 may be performed in accordance with examples as disclosed herein. In some examples, aspects of the operations of 1115 may be performed by a first encoder 835 as described with reference to FIG. 8.

At 1120, the method may include transmitting, based on applying the second mask vector, a message including at least the second set of shaped bits. The operations of 1120 may be performed in accordance with examples as disclosed herein. In some examples, aspects of the operations of 1120 may be performed by a message manager 840 as described with reference to FIG. 8.

FIG. 12 shows a flowchart illustrating a method 1200 that supports shaping code using serial processing in accordance with one or more aspects of the present disclosure. The operations of the method 1200 may be implemented by a UE or a network entity or its components as described herein. For example, the operations of the method 1200 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1205, the method may include generating, using a first decoder of the first device, a first set of shaping bits associated with a first subset of a set of information bits. The operations of 1205 may be performed in accordance with examples as disclosed herein. In some examples, aspects of the operations of 1205 may be performed by a first decoder 825 as described with reference to FIG. 8.

At 1210, the method may include generating, using a second decoder of the first device, a second set of shaping bits based on a first set of concatenated bits including at least the first set of shaping bits and a second subset of the set of information bits. The operations of 1210 may be performed in accordance with examples as disclosed herein. In some examples, aspects of the operations of 1210 may be performed by a second decoder 830 as described with reference to FIG. 8.

At 1215, the method may include applying a second mask vector to the first set of concatenated bits based on a first encoder of the first device to obtain a second set of shaped bits. The operations of 1215 may be performed in accordance with examples as disclosed herein. In some examples, aspects of the operations of 1215 may be performed by a first encoder 835 as described with reference to FIG. 8.

At 1220, the method may include transmitting, based on applying the second mask vector, a message including at least the second set of shaped bits. The operations of 1220 may be performed in accordance with examples as disclosed herein. In some examples, aspects of the operations of 1220 may be performed by a message manager 840 as described with reference to FIG. 8.

At 1225, the method may include applying a first mask vector to the first subset of the set of information bits based on a second encoder of the first device to obtain a first set of shaped bits, where the message further includes the first set of shaped bits. The operations of 1225 may be performed in accordance with examples as disclosed herein. In some examples, aspects of the operations of 1225 may be performed by a second encoder 845 as described with reference to FIG. 8.

At 1230, the method may include generating, using a third encoder of the first device, a set of parity bits based on the first set of shaped bits, the second set of shaped bits, and the second set of shaping bits, where the message further includes the set of parity bits. The operations of 1230 may be performed in accordance with examples as disclosed herein. In some examples, aspects of the operations of 1230 may be performed by a third encoder 875 as described with reference to FIG. 8.

FIG. 13 shows a flowchart illustrating a method 1300 that supports shaping code using serial processing in accordance with one or more aspects of the present disclosure. The operations of the method 1300 may be implemented by a UE or a network entity or its components as described herein. For example, the operations of the method 1300 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1305, the method may include generating, using a first decoder of the first device, a first set of shaping bits associated with a first subset of a set of information bits. The operations of 1305 may be performed in accordance with examples as disclosed herein. In some examples, aspects of the operations of 1305 may be performed by a first decoder 825 as described with reference to FIG. 8.

At 1310, the method may include generating, using a second decoder of the first device, a second set of shaping bits based on a first set of concatenated bits including at least the first set of shaping bits and a second subset of the set of information bits. The operations of 1310 may be performed in accordance with examples as disclosed herein. In some examples, aspects of the operations of 1310 may be performed by a second decoder 830 as described with reference to FIG. 8.

At 1315, the method may include applying a second mask vector to the first set of concatenated bits based on a first encoder of the first device to obtain a second set of shaped bits. The operations of 1315 may be performed in accordance with examples as disclosed herein. In some examples, aspects of the operations of 1315 may be performed by a first encoder 835 as described with reference to FIG. 8.

At 1320, the method may include transmitting, based on applying the second mask vector, a message including at least the second set of shaped bits. The operations of 1320 may be performed in accordance with examples as disclosed herein. In some examples, aspects of the operations of 1320 may be performed by a message manager 840 as described with reference to FIG. 8.

At 1325, the method may include generating, using a third decoder of the first device, a third set of shaping bits based on a second set of concatenated bits, the second set of concatenated bits including at least the second set of shaping bits and a third subset of the set of information bits. The operations of 1325 may be performed in accordance with examples as disclosed herein. In some examples, aspects of the operations of 1325 may be performed by a third decoder 850 as described with reference to FIG. 8.

At 1330, the method may include applying a third mask vector to the second set of concatenated bits based on a second encoder of the first device to obtain a third set of shaped bits. The operations of 1330 may be performed in accordance with examples as disclosed herein. In some examples, aspects of the operations of 1330 may be performed by a second encoder 845 as described with reference to FIG. 8.

At 1335, the method may include generating a third set of concatenated bits including at least the second set of shaped bits and the third set of shaping bits, where the message further includes the third set of concatenated bits. The operations of 1335 may be performed in accordance with examples as disclosed herein. In some examples, aspects of the operations of 1335 may be performed by a shaped bit manager 880 as described with reference to FIG. 8.

FIG. 14 shows a flowchart illustrating a method 1400 that supports shaping code using serial processing in accordance with one or more aspects of the present disclosure. The operations of the method 1400 may be implemented by a UE or a network entity or its components as described herein. For example, the operations of the method 1400 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1405, the method may include receiving a message including a set of multiple shaped bits and a first set of shaping bits, the set of multiple shaped bits including at least a first set of shaped bits and a second set of shaped bits. The operations of 1405 may be performed in accordance with examples as disclosed herein. In some examples, aspects of the operations of 1405 may be performed by a message manager 840 as described with reference to FIG. 8.

At 1410, the method may include decoding, based on the first set of shaping bits, the first set of shaped bits to obtain a first set of information bits and a second set of shaping bits. The operations of 1410 may be performed in accordance with examples as disclosed herein. In some examples, aspects of the operations of 1410 may be performed by a first decoder 825 as described with reference to FIG. 8.

At 1415, the method may include decoding, based on the second set of shaping bits, the second set of shaped bits to obtain a second set of information bits. The operations of 1415 may be performed in accordance with examples as disclosed herein. In some examples, aspects of the operations of 1415 may be performed by a second decoder 830 as described with reference to FIG. 8.

FIG. 15 shows a flowchart illustrating a method 1500 that supports shaping code using serial processing in accordance with one or more aspects of the present disclosure. The operations of the method 1500 may be implemented by a UE or a network entity or its components as described herein. For example, the operations of the method 1500 may be performed by a UE 115 or a network entity as described with reference to FIGS. 1 through 10. In some examples, a UE or a network entity may execute a set of instructions to control the functional elements of the UE or the network entity to perform the described functions. Additionally, or alternatively, the UE or the network entity may perform aspects of the described functions using special-purpose hardware.

At 1505, the method may include receiving a message including a set of multiple shaped bits and a first set of shaping bits, the set of multiple shaped bits including at least a first set of shaped bits and a second set of shaped bits. The operations of 1505 may be performed in accordance with examples as disclosed herein. In some examples, aspects of the operations of 1505 may be performed by a message manager 840 as described with reference to FIG. 8.

At 1510, the method may include decoding, based on the first set of shaping bits, the first set of shaped bits to obtain a first set of information bits and a second set of shaping bits. The operations of 1510 may be performed in accordance with examples as disclosed herein. In some examples, aspects of the operations of 1510 may be performed by a first decoder 825 as described with reference to FIG. 8.

At 1515, the method may include decoding, based on the second set of shaping bits, the second set of shaped bits to obtain a second set of information bits. The operations of 1515 may be performed in accordance with examples as disclosed herein. In some examples, aspects of the operations of 1515 may be performed by a second decoder 830 as described with reference to FIG. 8.

At 1520, the method may include decoding, based on the second set of shaping bits, the second set of shaped bits to obtain the second set of information bits and a third set of shaping bits. The operations of 1520 may be performed in accordance with examples as disclosed herein. In some examples, aspects of the operations of 1520 may be performed by a second decoder 830 as described with reference to FIG. 8.

The following provides an overview of aspects of the present disclosure:

Aspect 1: A method for wireless communications at a first device, comprising: generating, using a first decoder of the first device, a first set of shaping bits associated with a first subset of a set of information bits; generating, using a second decoder of the first device, a second set of shaping bits based at least in part on a first set of concatenated bits comprising at least the first set of shaping bits and a second subset of the set of information bits; applying a second mask vector to the first set of concatenated bits based at least in part on a first encoder of the first device to obtain a second set of shaped bits; and transmitting, based at least in part on applying the second mask vector, a message including at least the second set of shaped bits.

Aspect 2: The method of aspect 1, further comprising: applying a first mask vector to the first subset of the set of information bits based at least in part on the first encoder of the first device to obtain a first set of shaped bits, wherein the message further includes the first set of shaped bits.

Aspect 3: The method of aspect 2, further comprising: generating, using a third encoder of the first device, a set of parity bits based at least in part on the first set of shaped bits, the second set of shaped bits, and the second set of shaping bits, wherein the message further includes the set of parity bits.

Aspect 4: The method of any of aspects 1 through 3, further comprising: generating, using a third decoder of the first device, a third set of shaping bits based at least in part on a second set of concatenated bits, the second set of concatenated bits comprising at least the second set of shaping bits and a third subset of the set of information bits.

Aspect 5: The method of aspect 4, further comprising: applying a third mask vector to the second set of concatenated bits based at least in part on a second encoder of the first device to obtain a third set of shaped bits; and generating a third set of concatenated bits comprising at least the second set of shaped bits and the third set of shaping bits, wherein the message further includes the third set of concatenated bits.

Aspect 6: The method of aspect 5, further comprising: generating, using a third encoder of the first device, a set of parity bits based at least in part on the third set of concatenated bits, the second set of shaped bits, and the first subset of the set of information bits, wherein the message further includes the set of parity bits.

Aspect 7: The method of any of aspects 4 through 6, wherein a quantity of bits of the first subset of the set of information bits is greater than a quantity of bits of the third subset of the set of information bits.

Aspect 8: The method of any of aspects 1 through 7, wherein transmitting the message comprises: mapping the second set of shaped bits to one or more symbols to obtain a set of mapped bits; and transmitting, based at least in part on applying the second mask vector and on the mapping, a message including at least the set of mapped bits.

Aspect 9: The method of any of aspects 1 through 8, wherein generating the first set of shaping bits comprises: generating, using the first decoder of the first device, the first set of shaping bits associated with the first subset of the set of information bits based at least in part on one or more log-likelihood ratio values.

Aspect 10: The method of any of aspects 1 through 9, further comprising: determining that transmitting the message including at least the second set of shaped bits consumes less power than a transmission including the second subset of the set of information bits, wherein applying the second mask vector is based at least in part on the message consuming less power than the transmission.

Aspect 11: The method of any of aspects 1 through 10, wherein a quantity of bits of the first subset of the set of information bits is greater than a quantity of bits of the second subset of the set of information bits.

Aspect 12: A method for wireless communications at a second device, comprising: receiving a message including a plurality of shaped bits and a first set of shaping bits, the plurality of shaped bits comprising at least a first set of shaped bits and a second set of shaped bits; decoding, based at least in part on the first set of shaping bits, the first set of shaped bits to obtain a first set of information bits and a second set of shaping bits; and decoding, based at least in part on the second set of shaping bits, the second set of shaped bits to obtain a second set of information bits.

Aspect 13: The method of aspect 12, wherein the plurality of shaped bits further comprises a third set of shaped bits, and wherein decoding the second set of shaped bits further comprises: decoding, based at least in part on the second set of shaping bits, the second set of shaped bits to obtain the second set of information bits and a third set of shaping bits.

Aspect 14: The method of aspect 13, further comprising: decoding, based at least in part on the third set of shaping bits, the third set of shaped bits to obtain a third set of information bits.

Aspect 15: The method of aspect 14, wherein a quantity of bits of the third set of information bits is greater than a quantity of bits of the second set of information bits.

Aspect 16: The method of any of aspects 12 through 15, wherein decoding the first set of shaped bits comprises: applying a mask vector to the first set of shaped bits to obtain the first set of information bits and the second set of shaping bits, wherein the mask vector is based at least in part on the first set of shaping bits.

Aspect 17: The method of any of aspects 12 through 16, wherein a quantity of bits of the second set of information bits is greater than a quantity of bits of the first set of information bits.

Aspect 18: The method of any of aspects 12 through 17, further comprising: mapping the plurality of shaped bits and the first set of shaping bits to one or more symbols, wherein decoding the first set of shaped bits is based at least in part on the mapping.

Aspect 19: The method of any of aspects 12 through 18, wherein the message further includes a set of parity bits.

Aspect 20: An apparatus for wireless communications at a first device, comprising a processor; memory coupled with the processor; and instructions stored in the memory and executable by the processor to cause the apparatus to perform a method of any of aspects 1 through 11.

Aspect 21: An apparatus for wireless communications at a first device, comprising at least one means for performing a method of any of aspects 1 through 11.

Aspect 22: A non-transitory computer-readable medium storing code for wireless communications at a first device, the code comprising instructions executable by a processor to perform a method of any of aspects 1 through 11.

Aspect 23: An apparatus for wireless communications at a second device, comprising a processor; memory coupled with the processor; and instructions stored in the memory and executable by the processor to cause the apparatus to perform a method of any of aspects 12 through 19.

Aspect 24: An apparatus for wireless communications at a second device, comprising at least one means for performing a method of any of aspects 12 through 19.

Aspect 25: A non-transitory computer-readable medium storing code for wireless communications at a second device, the code comprising instructions executable by a processor to perform a method of any of aspects 12 through 19.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

The term “determine” or “determining” encompasses a variety of actions and, therefore, “determining” can include calculating, computing, processing, deriving, investigating, looking up (such as via looking up in a table, a database or another data structure), ascertaining and the like. Also, “determining” can include receiving (e.g., receiving information), accessing (e.g., accessing data stored in memory) and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. An apparatus at a first device, comprising:
memory; and
a processor coupled with the memory and configured to:
generate, using a first decoder of the first device, a first set of shaping bits associated with a first subset of a set of information bits;
generate, using a second decoder of the first device, a second set of shaping bits based at least in part on a first set of concatenated bits comprising at least the first set of shaping bits and a second subset of the set of information bits;
apply a second mask vector to the first set of concatenated bits based at least in part on a first encoder of the first device to obtain a second set of shaped bits; and
transmit, based at least in part on applying the second mask vector, a message including at least the second set of shaped bits.

2. The apparatus of claim 1, wherein the processor is further configured to:
apply a first mask vector to the first subset of the set of information bits based at least in part on the first encoder of the first device to obtain a first set of shaped bits, wherein the message further includes the first set of shaped bits.

3. The apparatus of claim 2, wherein the processor is further configured to:
generate, using a third encoder of the first device, a set of parity bits based at least in part on the first set of shaped bits, the second set of shaped bits, and the second set of shaping bits, wherein the message further includes the set of parity bits.

4. The apparatus of claim 1, wherein the processor is further configured to:
generate, using a third decoder of the first device, a third set of shaping bits based at least in part on a second set of concatenated bits, the second set of concatenated bits comprising at least the second set of shaping bits and a third subset of the set of information bits.

5. The apparatus of claim 4, wherein the processor is further configured to:
apply a third mask vector to the second set of concatenated bits based at least in part on a second encoder of the first device to obtain a third set of shaped bits; and
generate a third set of concatenated bits comprising at least the second set of shaped bits and the third set of shaping bits, wherein the message further includes the third set of concatenated bits.

6. The apparatus of claim 5, wherein the processor is further configured to:
generate, using a third encoder of the first device, a set of parity bits based at least in part on the third set of concatenated bits, the second set of shaped bits, and the first subset of the set of information bits, wherein the message further includes the set of parity bits.

7. The apparatus of claim 4, wherein a quantity of bits of the first subset of the set of information bits is greater than a quantity of bits of the third subset of the set of information bits.

8. The apparatus of claim 1, wherein, to transmit the message, the processor is configured to:
map the second set of shaped bits to one or more symbols to obtain a set of mapped bits; and
transmit, based at least in part on applying the second mask vector and on the mapping, a message including at least the set of mapped bits.

9. The apparatus of claim 1, wherein the processor is further configured to:
generate, using the first decoder of the first device, the first set of shaping bits associated with the first subset of the set of information bits based at least in part on one or more log-likelihood ratio values.

10. The apparatus of claim 1, wherein the processor is further configured to:
determine that transmitting the message including at least the second set of shaped bits consumes less power than a transmission including the second subset of the set of information bits, wherein applying the second mask vector is based at least in part on the message consuming less power than the transmission.

11. The apparatus of claim 1, wherein a quantity of bits of the first subset of the set of information bits is greater than a quantity of bits of the second subset of the set of information bits.

12. An apparatus for wireless communications at a second device, comprising:
memory; and
a processor coupled with the memory and configured to:
receive a message including a plurality of shaped bits and a first set of shaping bits, the plurality of shaped bits comprising at least a first set of shaped bits and a second set of shaped bits;
decode, based at least in part on the first set of shaping bits, the first set of shaped bits to obtain a first set of information bits and a second set of shaping bits; and
decode, based at least in part on the second set of shaping bits, the second set of shaped bits to obtain a second set of information bits.

13. The apparatus of claim 12, wherein, to decode the second set of shaped bits, the processor is configured to:
decode, based at least in part on the second set of shaping bits, the second set of shaped bits to obtain the second set of information bits and a third set of shaping bits.

14. The apparatus of claim 13, wherein the processor is further configured to:
decode, based at least in part on the third set of shaping bits, the third set of shaped bits to obtain a third set of information bits.

15. The apparatus of claim 14, wherein a quantity of bits of the third set of information bits is greater than a quantity of bits of the second set of information bits.

16. The apparatus of claim 12, wherein, to decode the first set of shaped bits, the processor is configured to:
apply a mask vector to the first set of shaped bits to obtain the first set of information bits and the second set of shaping bits, wherein the mask vector is based at least in part on the first set of shaping bits.

17. The apparatus of claim 12, wherein a quantity of bits of the second set of information bits is greater than a quantity of bits of the first set of information bits.

18. The apparatus of claim 12, wherein the processor is further configured to:
map the plurality of shaped bits and the first set of shaping bits to one or more symbols, wherein decoding the first set of shaped bits is based at least in part on the mapping.

19. The apparatus of claim 12, wherein the message further includes a set of parity bits.

20. A method for wireless communications at a first device, comprising:
generating, using a first decoder of the first device, a first set of shaping bits associated with a first subset of a set of information bits;
generating, using a second decoder of the first device, a second set of shaping bits based at least in part on a first set of concatenated bits comprising at least the first set of shaping bits and a second subset of the set of information bits;
applying a second mask vector to the first set of concatenated bits based at least in part on a first encoder of the first device to obtain a second set of shaped bits; and
transmitting, based at least in part on applying the second mask vector, a message including at least the second set of shaped bits.

21-30. (canceled)
